(19) United States
(12) Patent Application Publication
(10) Pub. No.: US 2024/0222376 A1
(43) Pub. Date: Jul. 4, 2024

(54) TECHNOLOGIES FOR RIBBON FIELD EFFECT TRANSISTORS WITH VARIABLE FIN CHANNEL DIMENSIONS

(71) Applicant: Intel Corporation, Santa Clara, CA (US)

(72) Inventors: Marko Radosavljevic, Portland, OR (US); Jami A. Wiedemer, Scappoose, OR (US); Munzarin F. Qayyum, Hillsboro, OR (US); Cheng-Ying Huang, Vancouver, WA (US); Rohit V. Galatage, Portland, OR (US); Evan A. Clinton, Carrollton, GA (US)

(73) Assignee: Intel Corporation, Santa Clara, CA (US)

(21) Appl. No.: 18/091,714

(22) Filed: Dec. 30, 2022

(51) Int. Cl. H01L 27/092; H01L 21/822; H01L 21/8238; H01L 29/06; H01L 29/08; H01L 29/10; H01L 29/423; H01L 29/66; H01L 29/775

(52) U.S. Cl. CPC H01L 27/0922; H01L 21/8221; H01L 21/823807; H01L 21/823814; H01L 29/0673; H01L 29/0847; H01L 29/1033; H01L 29/42392; H01L 29/66439; H01L 29/775

(57) ABSTRACT

Technologies for ribbon field-effect transistors with variable nanoribbon channel dimensions are disclosed. In an illustrative embodiment, a stack of semiconductor nanoribbons are formed, with each semiconductor nanoribbon having a source region, a channel region, and a drain region. Some or all of the channel regions can be selectively narrowed and/or thinned, allowing for the drive and/or leakage current to be tuned. In some embodiments, one or more of the semiconductor nanoribbons near the top of the stack can be narrowed and/or thinned. In other embodiments, one or more of the semiconductor nanoribbons at or closer to the bottom of the stack can be narrowed and/or thinned.

### BACKGROUND

Transistors are ubiquitous devices present in virtually all electronic devices. As the density of transistors continues to increase, new architectures such as fin field effect transistors (FETs) and ribbon FET are used to reduce the footprint of a transistor. A ribbon FET may include several nanoribbons vertically stacked on top of each other. In some cases, a circuit designed may want to remove one or more of the nanoribbons for, e.g., adjusting the drive and/or adjusting leakage current. In order to control the dimensions of nanoribbon channels in a particular transistor, layer transfer may be used. However, layer transfer can lead to issues such as a high parasitic capacitance.

### BRIEF DESCRIPTION OF THE DRAWINGS

FIG. 1 is an isometric view of a ribbon field-effect transistor (FET).

FIG. 1 is an isometric view of the transistor of FIG. 1.

FIG. 2 is a cross-sectional side view of one embodiment of the transistor of FIG. 1.

FIG. 3 is a cross-sectional side view of one embodiment of the transistor of FIG. 1.

FIG. 4 is a cross-sectional side view of one embodiment of the transistor of FIG. 1.

FIG. 5 is a cross-sectional side view of one embodiment of the transistor of FIG. 1.

FIG. 6 is a simplified flow diagram of at least one embodiment of a method for selectively narrowing a nanoribbon in a ribbon FET.

FIG. 7 is a cross-sectional side view at one step of the flow diagram of FIG. 6.

FIG. 8 is a cross-sectional side view at one step of the flow diagram of FIG. 6.

FIG. 9 is a cross-sectional side view at one step of the flow diagram of FIG. 6.

FIG. 10 is a cross-sectional side view at one step of the flow diagram of FIG. 6.

FIG. 11 is a cross-sectional side view at one step of the flow diagram of FIG. 6.

FIG. 12 is a cross-sectional side view of one embodiment of the transistor of FIG. 1.

FIG. 13 is a simplified flow diagram of at least one embodiment of a method for selectively narrowing a nanoribbon in a ribbon FET.

FIG. 14 is a cross-sectional side view at one step of the flow diagram of FIG. 13.

FIG. 15 is a cross-sectional side view at one step of the flow diagram of FIG. 13.

FIG. 16 is a cross-sectional side view at one step of the flow diagram of FIG. 13.

FIG. 17 is a cross-sectional side view at one step of the flow diagram of FIG. 13.

FIG. 18 is a cross-sectional side view at one step of the flow diagram of FIG. 13.

FIG. 19 is a cross-sectional side view at one step of the flow diagram of FIG. 13.

FIG. 20 is a cross-sectional side view at one step of the flow diagram of FIG. 13.

FIG. 21 is a cross-sectional side view at one step of the flow diagram of FIG. 13.

FIG. 22 is a cross-sectional side view of one embodiment of the transistor of FIG. 1.

FIG. 23 is a simplified flow diagram of at least one embodiment of a method for selectively removing a nanoribbon from a ribbon FET.

FIG. 24 is a cross-sectional side view at one step of the flow diagram of FIG. 7.

FIG. 25 is a cross-sectional side view at one step of the flow diagram of FIG. 7.

FIG. 26 is a cross-sectional side view at one step of the flow diagram of FIG. 7.

FIG. 27 is a cross-sectional side view at one step of the flow diagram of FIG. 7.

FIG. 28 is a cross-sectional side view of one embodiment of the transistor of FIG. 1.

FIG. 29 is a simplified flow diagram of at least one embodiment of a method for selectively removing a nanoribbon from a ribbon FET.

FIG. 30 is a cross-sectional side view at one step of the flow diagram of FIG. 7.

FIG. 31 is a cross-sectional side view at one step of the flow diagram of FIG. 7.

FIG. 32 is a cross-sectional side view at one step of the flow diagram of FIG. 7.

FIG. 33 is a cross-sectional side view at one step of the flow diagram of FIG. 7.

FIG. 34 is a cross-sectional side view at one step of the flow diagram of FIG. 7.

FIG. 35 is a cross-sectional side view at one step of the flow diagram of FIG. 7.

FIG. 36 is a top view of a wafer and dies that may be included in a microelectronic assembly, in accordance with any of the embodiments disclosed herein.

FIG. 37 is a cross-sectional side view of an integrated circuit device that may be included in a microelectronic assembly, in accordance with any of the embodiments disclosed herein.

FIGS. 38A-38D are perspective views of example planar, NanoribbonFET, gate-all-around, and stacked gate-all-around transistors.

FIG. 39 is a cross-sectional side view of an integrated circuit device assembly that may include a microelectronic assembly, in accordance with any of the embodiments disclosed herein.

FIG. 40 is a block diagram of an example electrical device that may include a microelectronic assembly, in accordance with any of the embodiments disclosed herein.

### DETAILED DESCRIPTION

In one embodiment disclosed herein, as described in more detail below, several semiconductor nanoribbons may be arranged in a vertical stack as part of manufacturing one or more transistors. Initially, all groups of semiconductor nanoribbons in an area may have the same dimensions for the channel regions. In order to control the drive and/or leakage current as well as tune the P/N ratio in a CMOS device, a circuit designer may want to reduce the width and/or height of semiconductor nanoribbons in some of the stacks. As disclosed in further detail below, various approaches may be used to protect some of the semiconductor nanoribbons while etching away part of others of the semiconductor nanoribbons, changing the width of some semiconductor nanoribbons in a stack.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a substrate assembly feature, such as a through width, that is described as having substantially a listed dimension can vary within a few percent of the listed dimension.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the terms “upper”/“lower” or “above”/“below” may refer to relative locations of an object (e.g., the surfaces described above), especially in light of examples shown in the attached figures, rather than an absolute location of an object. For example, an upper surface of an apparatus may be on an opposite side of the apparatus from a lower surface of the object, and the upper surface may be facing upward generally only when viewed in a particular way. As another example, a first object above a second object may be on or near an “upper” surface of the second object rather than near a “lower” surface of the object, and the first object may be truly above the second object only when the two objects are viewed in a particular way.

References are made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document. Different parts of the drawings with the same hatchings refer to the same component or material unless labeled otherwise.

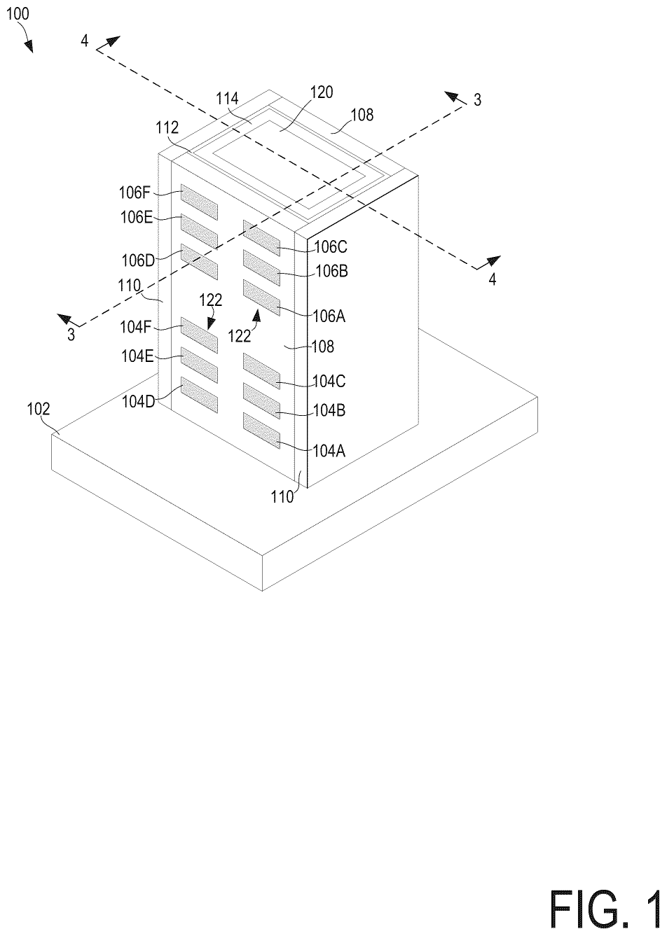

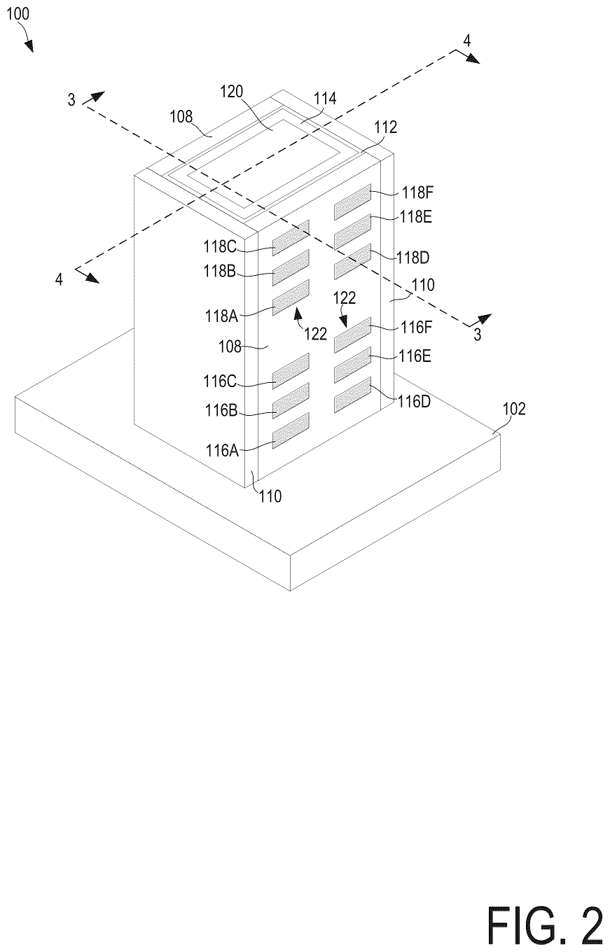

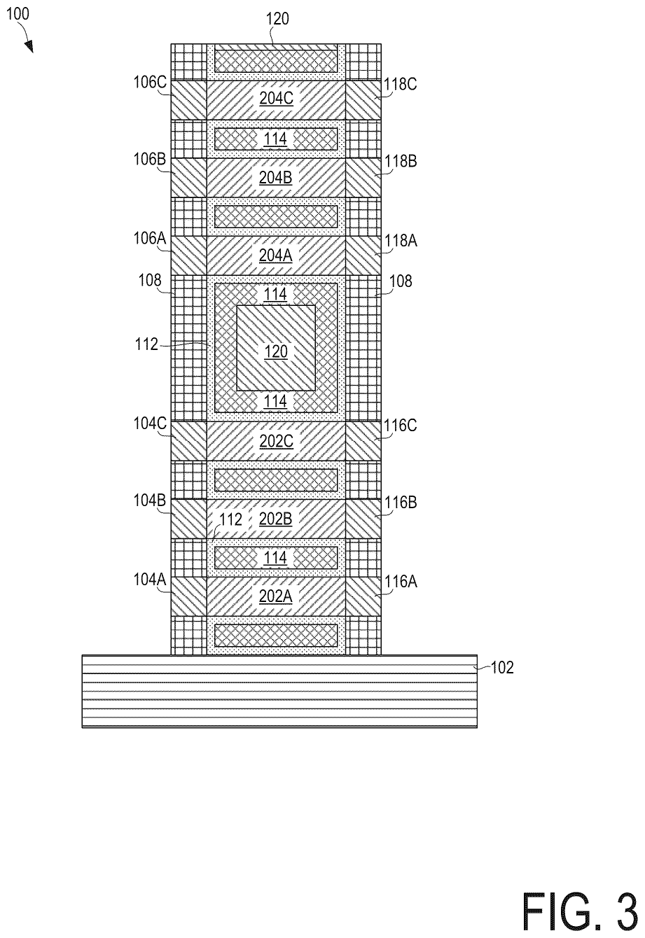

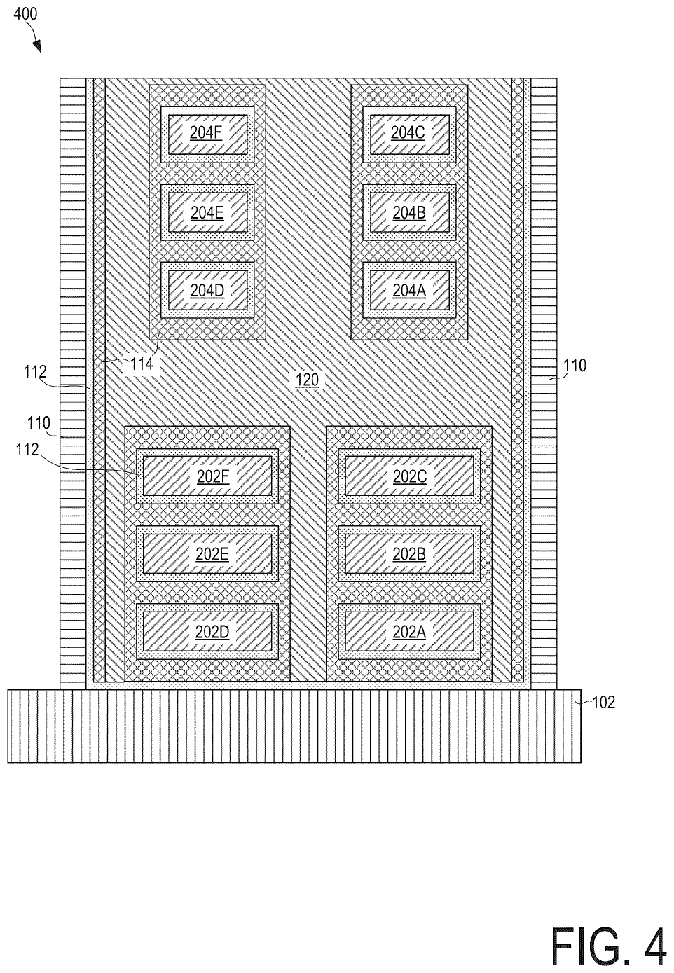

Referring now to FIGS. 1-4, in one embodiment, FIG. 1 shows one perspective view of one or more ribbon FETs 100, FIG. 2 shows another perspective view of the one or more ribbon FETs 100, FIG. 3 shows a cross-sectional view of the one or more ribbon FETs 100 taken from view 3 labeled in FIG. 1, and FIG. 4 shows a cross-sectional view of one embodiment of the ribbon FET structure 100 taken from view 4 labeled in FIG. 1. In some embodiments, the one or more ribbon FETs 100 may also be referred to as a gate-all-around transistor, a nanoribbon transistor, a nanowire transistor, a nanosheet transistor, etc.

The one or more ribbon FETs 100 are supported by a substrate 102. The one or more ribbon FETs 100 has one or more semiconductor nanoribbons 122 for one or more transistors. In the illustrative embodiment, the one or more ribbon FETs 100 include semiconductor nanoribbons 122 for one or more NMOS transistors and nanoribbons for one or more PMOS transistors. In the illustrative embodiment, the bottom semiconductor nanoribbons 122 are for an NMOS transistor, and the top semiconductor nanoribbons 122 are for a PMOS transistor. The gate of the PMOS transistor may be connected to the gate of the NMOS transistor below it, allowing the PMOS and NMOS transistor to work together as CMOS transistors. The bottom semiconductor nanoribbons 122 include source regions 104A-F, channel regions 202A-F (see FIGS. 3 and 4), and drain regions 116A-F (see FIG. 2). The top semiconductor nanoribbons 122 include source regions 106A-F, channel regions 204A-F (see FIGS. 3 and 4), and drain regions 118A-F. Dielectric spacers 108 are in between the source/drain regions 104A-F, 106A-F, 116A-F, and 118A-F at either end of the channel regions 202A-F, 204A-F.

It should be appreciated that relative words such as top, bottom, above, below etc., are merely describing the position of components relative to another component, such as the substrate. The use of words such as top, bottom, above, below, etc., do not require a particular orientation of the one or more ribbon FETs 100 as a whole.

Dielectric isolation layers 110 surround the channel regions 202A-F, 204A-F and other structures of the transistor 100. A dielectric layer 112 surrounds the channel regions 202A-F, 204A-F inside the region bounded by the dielectric spacers 108 and the dielectric isolation layers 110. The gate 114 surrounds the dielectric layer 112 and the channel regions 202A-F, 204A-F. A conductive material 120 fills the rest of the region denanoribboned by the dielectric spacers 108 and the dielectric isolation layers 110.

As shown in FIG. 4, the channel regions 204A-204F are narrower in width than the channel regions 202A-F below them. The channel regions 204A-204F may be narrower by any suitable amount, such as being 20-90% of the width of the channel regions 202A-202F. The channel regions 204A-204F have been narrowed after the stack of nanoribbons 122 has been deposited, as discussed in more detail below. Narrowing the width of the channel regions 202A-F can be used to adjust the drive and/or leakage current as well as tune the P/N ratio in a CMOS device. Alternatives to the solutions presented below include using layer transfer. However, layer transfer would result in a relatively large gap between the semiconductor nanoribbons 122 that are part of the lower transistor and the semiconductor nanoribbons 122 that are part of the upper transistor. For example, the gap between the source region 104F and the source region 106D using layer transfer may be, e.g., 50 nanometers. The gap between the source region 104F and the source region 106D using the techniques described herein may be, e.g., 5-30 nanometers.

The substrate 102 supports the rest of the one or more ribbon FETs 100. In the illustrative embodiment, the substrate 102 is silicon. In other embodiments, the substrate 102 may be, e.g., silicon oxide, gallium nitride, a perovskite, strontium titanium oxide, etc.

The semiconductor nanoribbons 122 may be made from any suitable material or combination of materials, such as a doped semiconductor. In the illustrative embodiment, the channel regions 202A-F are n-doped silicon, such as silicon doped with phosphorous or arsenic, and the channel regions 204A-F are p-doped silicon, such as silicon doped with boron or gallium. The illustrative source regions 104A-F and drain regions 116A-F are silicon germanium doped with boron or gallium. The illustrative source regions 106A-F and drain regions 118A-F are silicon doped with phosphorous or arsenic. More generally, the source regions 104A-F, drain regions 116A-F, source regions 106A-F, drain regions 118A-F, channel regions 202A-F, and channel regions 204A-F may be made of any suitable combination of doped or undoped semiconductors. In some embodiments, some or all of the source regions 104A-F, drain regions 116A-F, source regions 106A-F, drain regions 118A-F, channel regions 202A-F, and channel regions 204A-F may be perovskites.

In some embodiments, some or all of the source regions 104A-F, drain regions 116A-F, source regions 106A-F, and/or drain regions 118A-F may extend past the spacers 108. In the illustrative embodiment, the one or more ribbon FETs 100 are symmetric, and there is no structural distinction between, e.g., the source regions 104A-F and the drain regions 116A-F. The source regions 104A-F, drain regions 116A-F, source regions 106A-F, drain regions 118A-F, channel regions 202A-F, and channel regions 204A-F may have any suitable dimensions, such as a thickness or width of, e.g., 0.5-20 nanometers and a length of, e.g., 2-50 nanometers. Each of the one or more ribbon FETs 100 may include any suitable number of semiconductor nanoribbons 122, such as 1-8. An electrode may be disposed at either end of the source regions 104A-F, drain regions 116A-F, source regions 106A-F, and/or drain regions 118A-F (not shown in the figures).

In the illustrative embodiment, the dielectric spacers 108 are a low-k material such as, e.g., silicon oxide or silicon nitride. The dielectric isolation layers 110 may be made of any suitable material, such as silicon oxide or silicon nitride. The dielectric isolation layers 110 may have any suitable dimension, such as a length along the substrate 102 of, e.g., 2-50 nanometers, a height of, e.g., 5-50 nanometers, and a width of, e.g., 2-30 nanometers. In the illustrative embodiment, the channel regions 202A-C and 204A-C (and their corresponding source/drain regions) are the same width and height as channel regions 202D-F and 204D-F (and their corresponding source/drain regions). In other embodiments, the channels regions 202A-C and 204A-C (and their corresponding source/drain regions) may be wider, less wide, thicker, or less thick than the channel regions 202D-F and 204D-F (and their corresponding source/drain regions).

The dielectric layer 112 may be any suitable dielectric, such as a high-K dielectric. In the illustrative embodiment, the dielectric layer is hafnium oxide. The dielectric layer 112 may have any suitable thickness, such as a thickness of about 0.5-25 nanometers.

The illustrative gate 114 may include at least one p-type work function metal or n-type work function metal, depending on whether the transistor is to be a p-type metal oxide semiconductor (PMOS) or an n-type metal oxide semiconductor (NMOS) transistor. In some implementations, the gate 114 may consist of a stack of two or more metal layers, where one or more metal layers are work function metal layers and at least one metal layer is a fill metal layer. For a PMOS transistor, metals that may be used for the gate 114 include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate 114 include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

The conductive material 120 that is adjacent the gate 114 may be any suitable conductor. In the illustrative embodiment the conductive material 120 is tungsten.

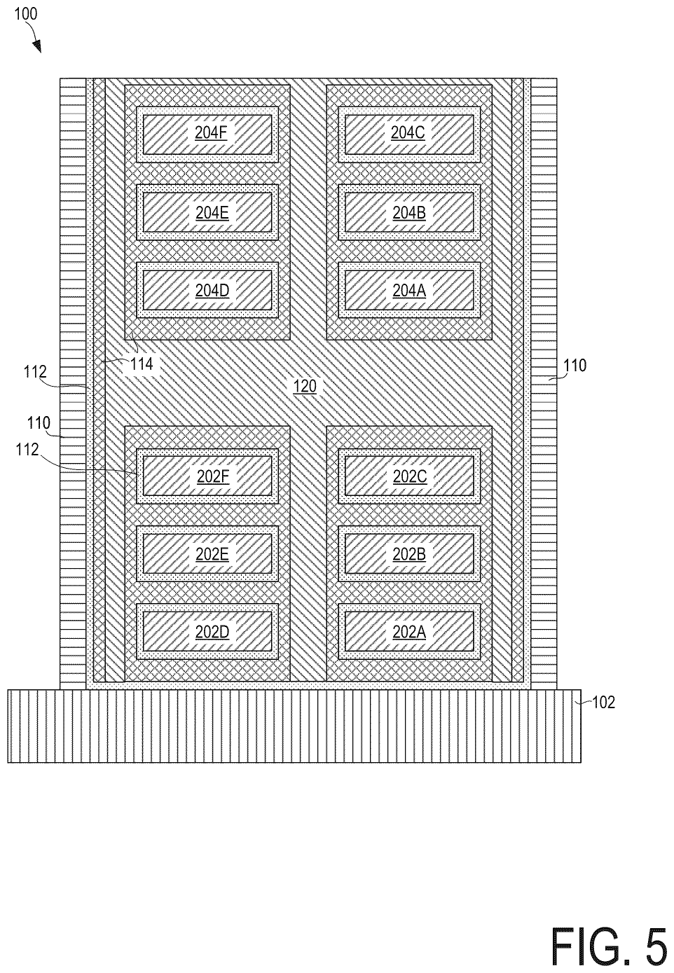

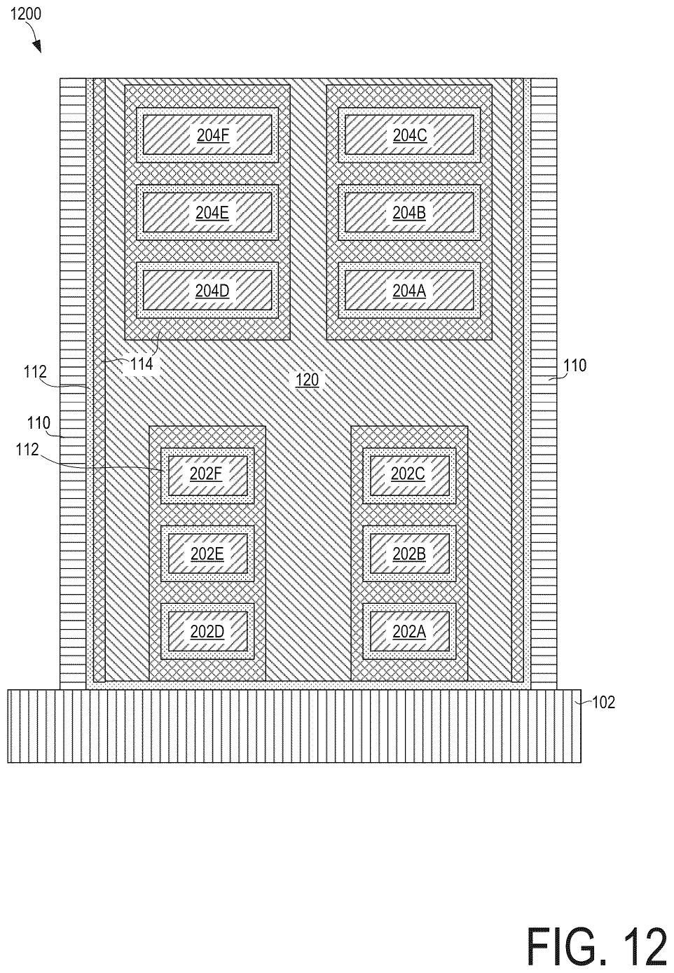

It should be noted that the techniques described below to narrow the channel regions of semiconductor nanoribbons 122 may be done at the level of a single transistor. For example, in one embodiment, the one or more ribbon FETs 100 may have channel regions narrowed from some of the semiconductor nanoribbons 122, and one or more ribbon FETs 500 nearby or adjacent ribbon FETs 100 may have channel regions that are not narrowed, as shown in FIG. 5. Additionally or alternatively, the channel regions 202A-202F of some or all of the lower semiconductor nanoribbons 122 may be narrowed, as discussed in more detail below in regard to FIGS. 12-21.

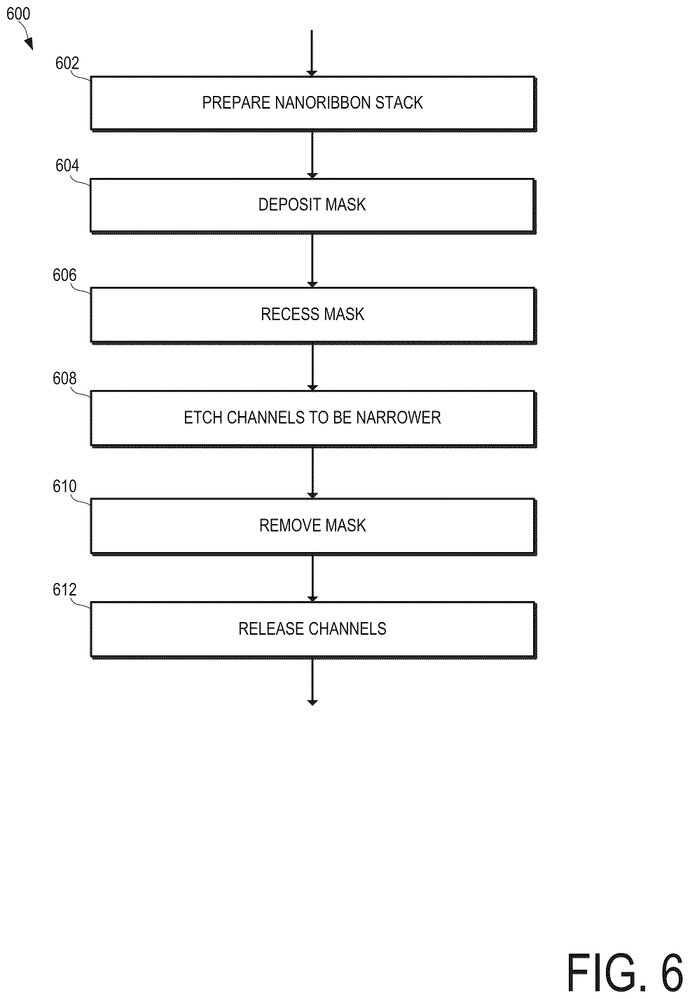

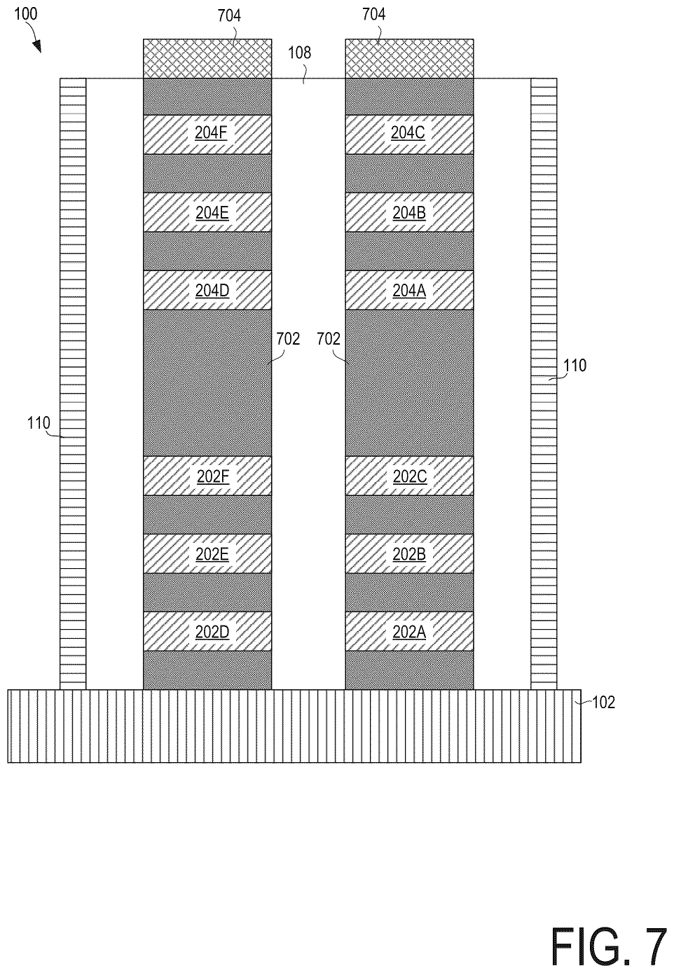

Referring now to FIG. 6, in one embodiment, a flowchart for a method 600 for narrowing one or more channels from a transistor structure is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, causes the machine to perform some or all of the steps of the method 600. The method 600 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, plasma etching, reactive ion etching, ion-assisted chemical vapor etching, thermal treatments, etc. FIGS. 7-11 show various stages of the method 600 from the same perspective as FIG. 4.

The method 600 begins in block 602, in which a stack of semiconductor nanoribbons 122 is prepared, including the source regions 104A-F, 106A-F, the drain regions 116A-F, 118A-F, the dielectric spacers 108, and the dielectric isolation layers 110. One or more layers of inter-nanoribbon layers 702 are present as well, as shown in FIG. 7, before the nanoribbons 122 are released from those layers 702 later in the method. In the illustrative embodiment, the inter-nanoribbon layers 702 are silicon-germanium. In other embodiments, the layers 702 may be made of any suitable material. In the illustrative embodiment, a cap 704 is on top of each stack of nanoribbons 122. The illustrative caps 704 are made of silicon nitride. In other embodiments, the caps 704 may be made of a different material.

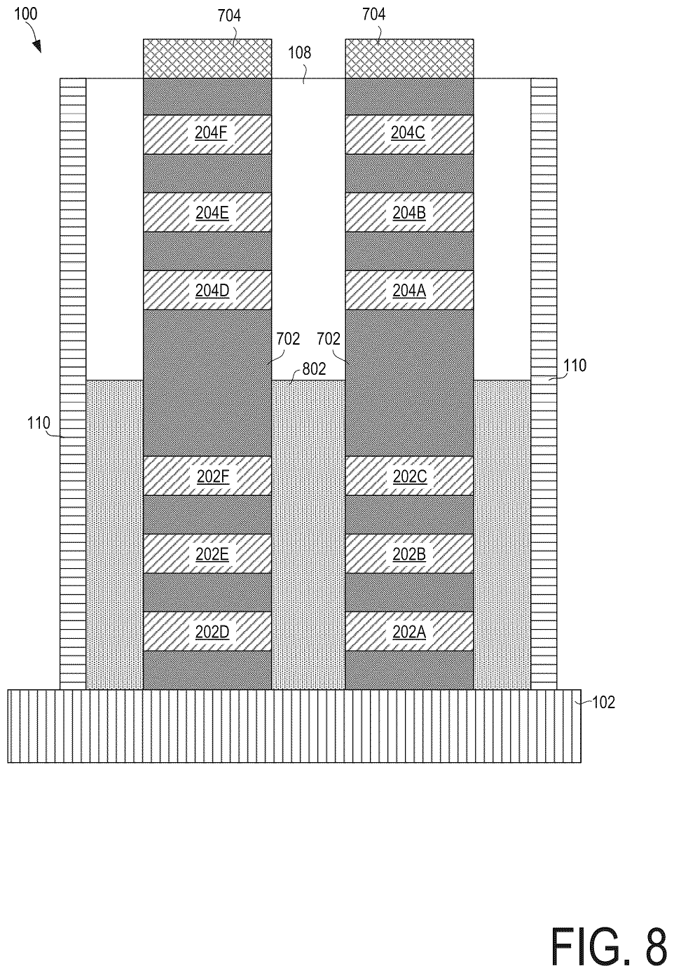

In block 604 a mask 802 is applied. In block 606, the mask 802 is recessed, exposing the channel regions 204A-204F, as shown in FIG. 8. In the illustrative embodiment, the mask 802 is a carbon hard mask. In other embodiments, the mask 802 may be a different material.

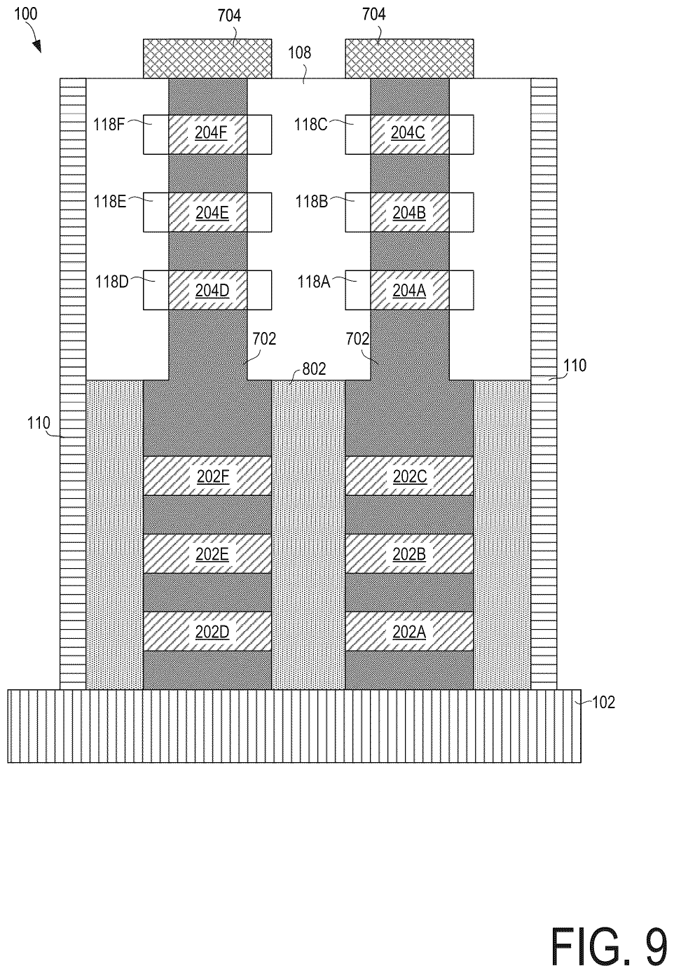

In block 608, the channel regions 204A-204F are partially etched to narrow the channel regions 204A-204F, as shown in FIG. 9. The channel regions 204A-204F may be narrowed by any suitable amount, such as being 20-90% of the width of the channel regions 202A-202F. The mask 802 prevents the channel regions 202A-202F from being etched as well. The source regions 106A-F and drain regions 118A-F are partially exposed once the channels 204A-F are removed. Depending on the particular materials, dopants, etc., of the source regions 106A-F and drain regions 118A-F, part of the source regions 106A-F and/or drain regions 118A-F may be partially etched away as well, either at block 608 or a later block or processing step.

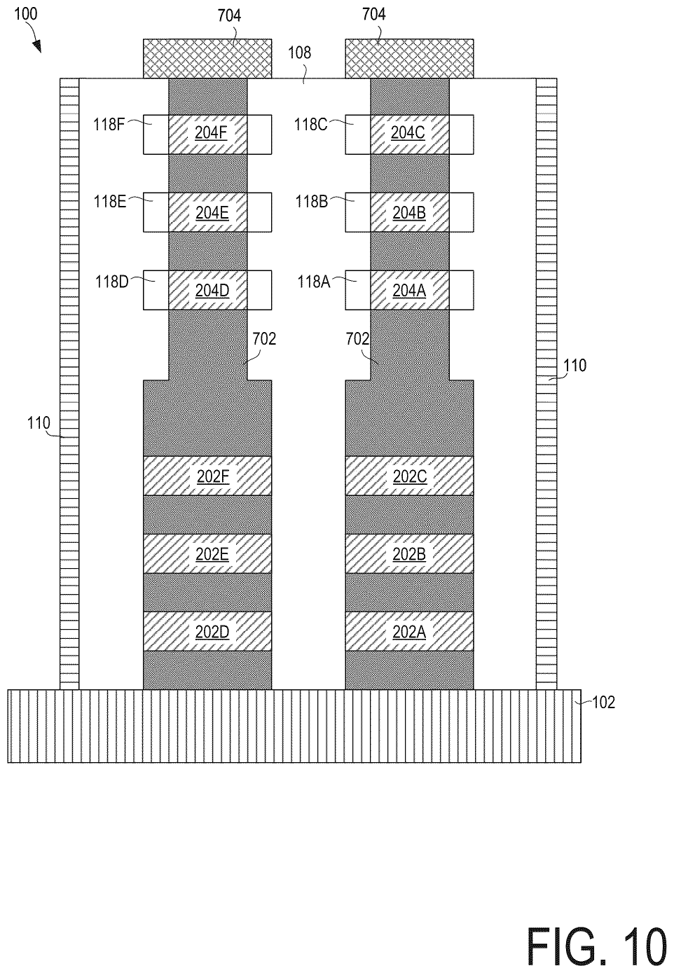

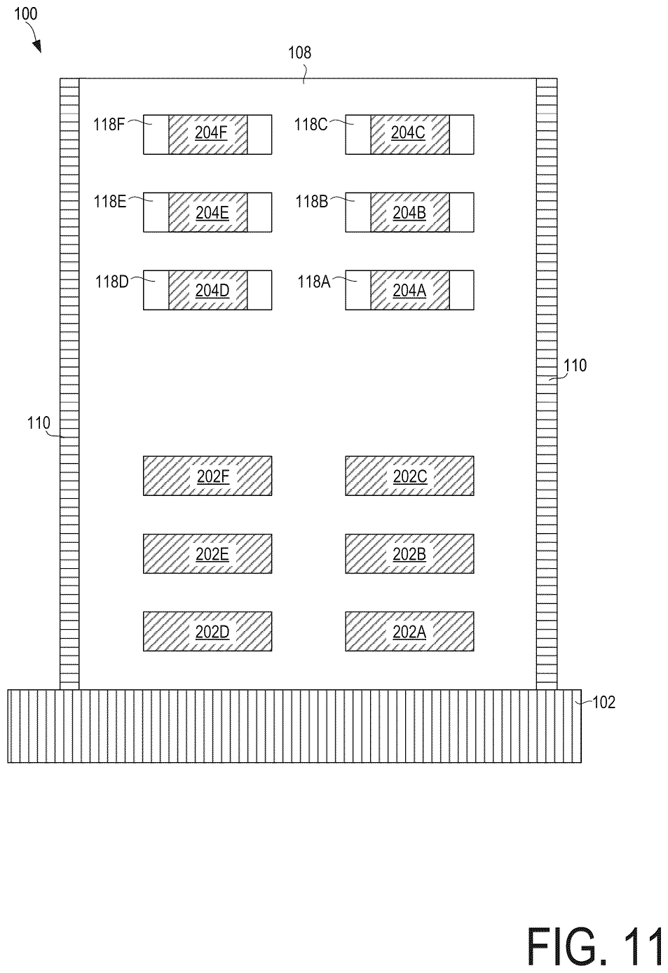

In block 610, the mask 802 is removed, as shown in FIG. 10. The channel regions 202A-F, 204A-F are released from the inter-nanoribbon layers 702 in block 612, as shown in FIG. 11.

Referring now to FIG. 12, in one embodiment, one or more ribbon FETs 1200 are shown. The one or more ribbon FETs 1200 may be similar to the one or more FETs 100 described above, and similar components may have similar or the same labels. A description of the aspects of the one or more ribbon FETs 1200 that are similar or the same as the one or more ribbon FETs 100 will not be repeated in the interest of clarity. In the illustrative one or more ribbon FETs 1200, the channels 202A-F are narrower than the channels 204A-F above them, as shown in FIG. 12. The channel regions 202A-202F may be narrower by any suitable amount, such as being 20-90% of the width of the channel regions 204A-204F.

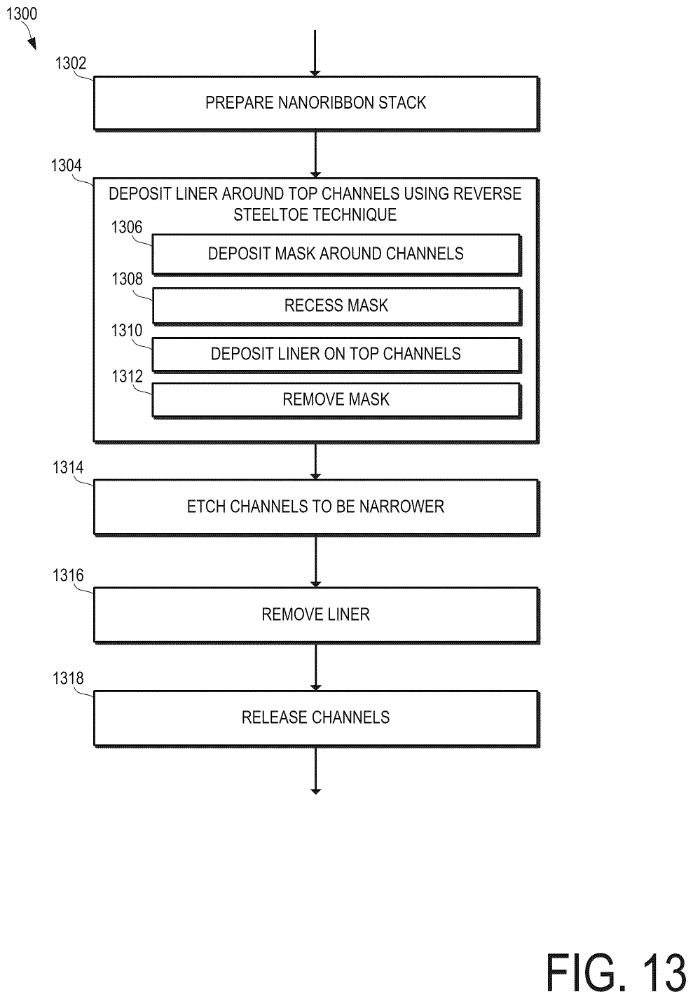

Referring now to FIG. 13, in one embodiment, a flowchart for a method 1300 for narrowing one or more channels of a transistor structure is shown. The method 1300 may be executed in a similar manner and using similar techniques as the method 600 above. In some cases, similar materials such as liners and masks may be used in the method 1300 in a similar manner as the method 600. The details of the techniques, materials, etc., of the method 600 will not be repeated in the interest of clarity.

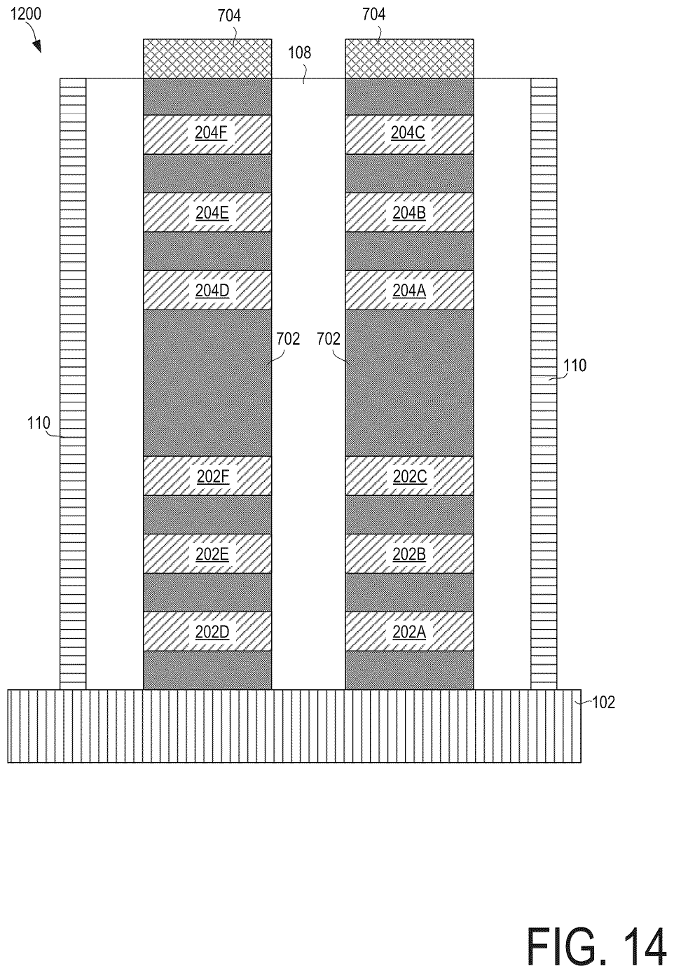

The method 1300 begins in block 1302, in which a stack of semiconductor nanoribbons 122 is prepared, including the source regions 104A-F, 106A-F, the drain regions 116A-F, 118A-F, the dielectric spacers 108, and the dielectric isolation layers 110. One or more layers of inter-nanoribbon layers 702 are present as well, as shown in FIG. 14, before the nanoribbons 122 are released from those layers 702 later in the method.

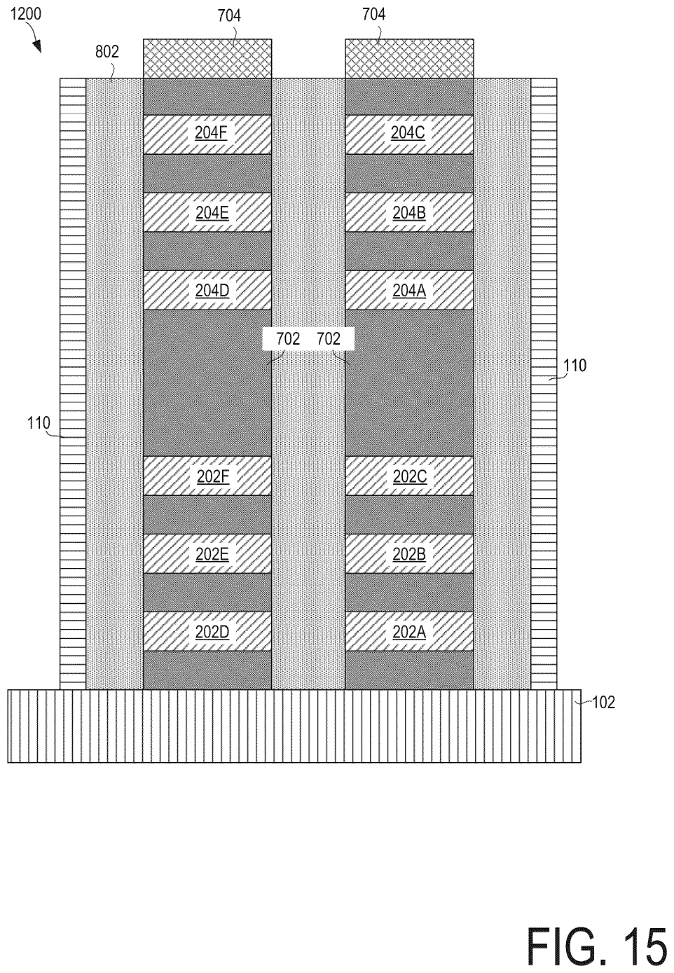

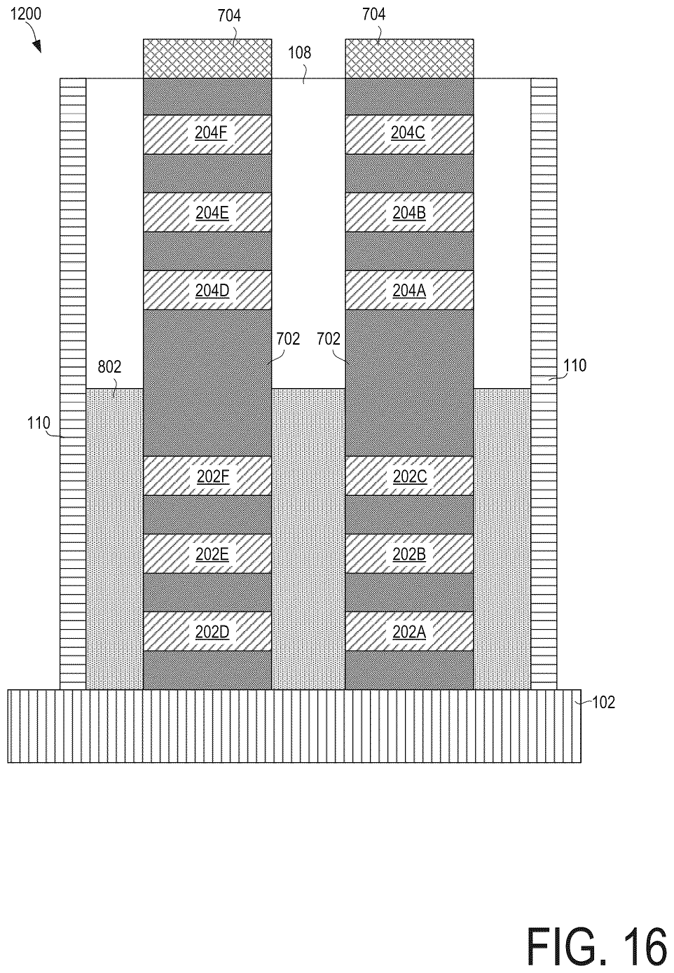

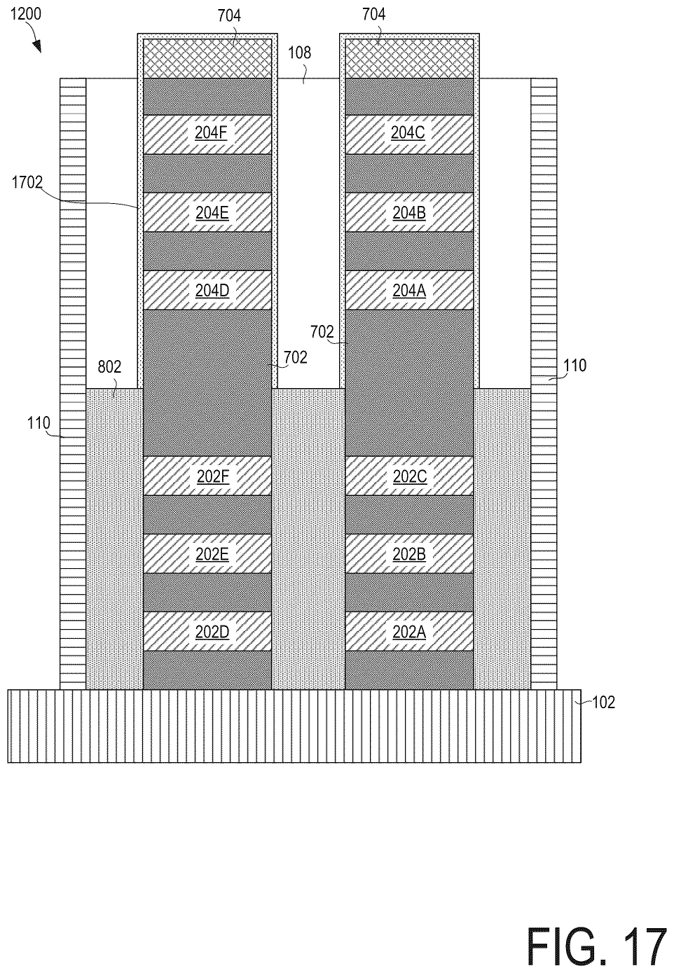

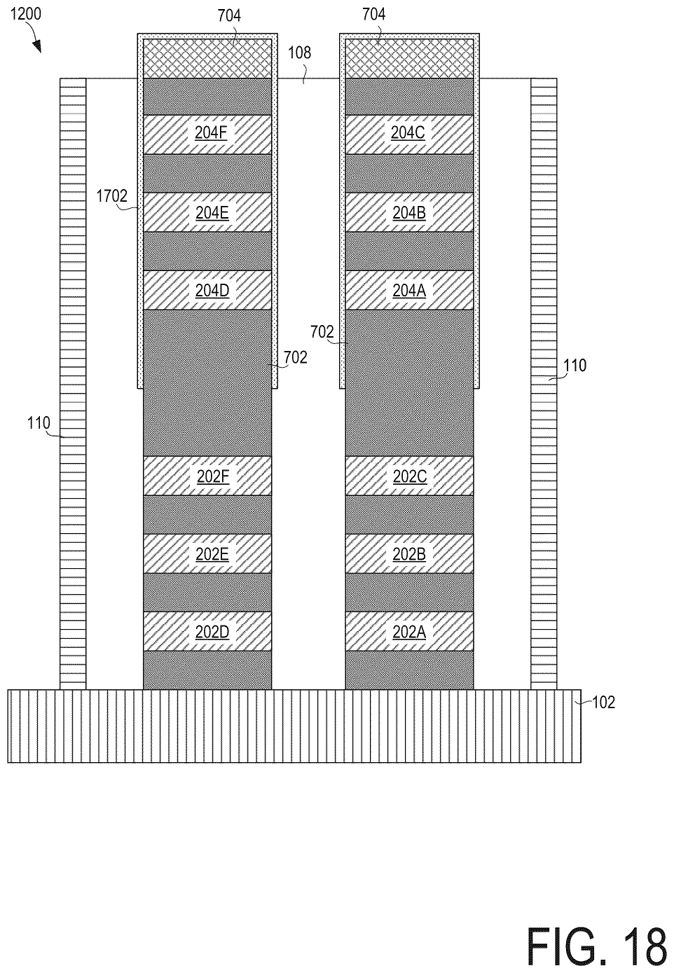

In block 1304, a liner 1702 is deposited around the channel regions 204A-F using a technique which may be referred to as a reverse steel toe technique. To do so, in block 1306, a mask 802 is deposited around the channel regions 202A-F, 204A-F, as shown in FIG. 15. In block 1308, the mask 802 is then recessed to expose the channel regions 204A-204F, as shown in FIG. 16. In block 1310, the liner 1702 is then deposited on the top channel regions 204A-F, as shown in FIG. 17. In block 1512, the mask 802 is removed, leaving the liner 1702 behind, as shown in FIG. 18.

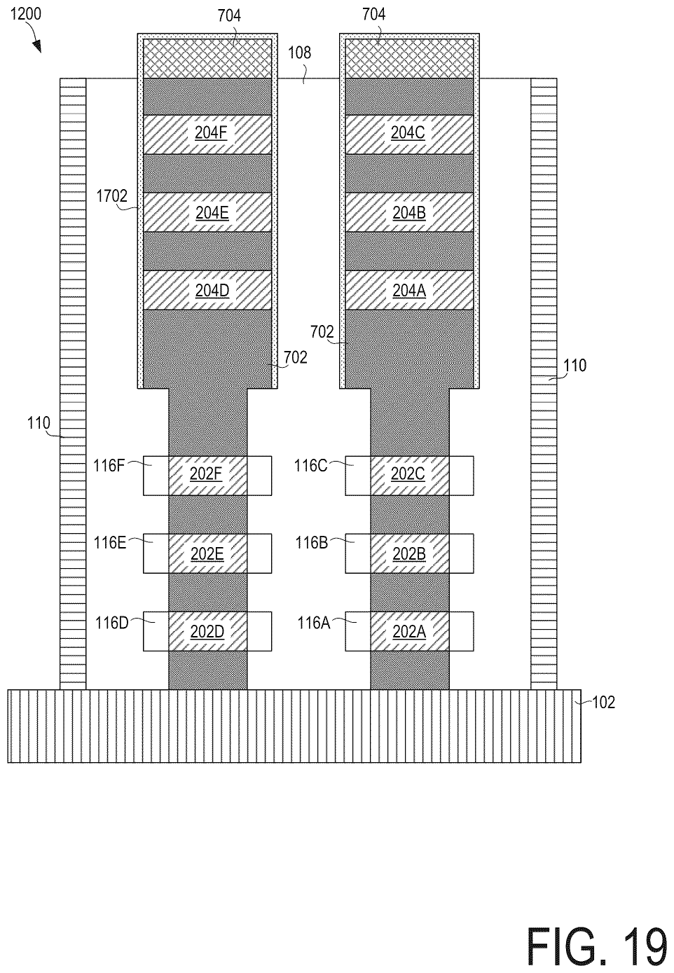

In block 1314, the channel regions 202A-202F are partially etched to narrow the channel regions 202A-202F, as shown in FIG. 19. The channel regions 202A-202F may be narrower by any suitable amount, such as being 20-90% of the width of the channel regions 204A-204F. The liner 1702 prevents the channel regions 204A-204F from being etched as well. The source regions 104A-F and drain regions 116A-F are partially exposed once the channels 202A-F are removed. Depending on the particular materials, dopants, etc., of the source regions 104A-F and drain regions 116A-F, part of the source regions 104A-F and/or drain regions 116A-F may be partially etched away as well, either at block 1314 or a later block or processing step.

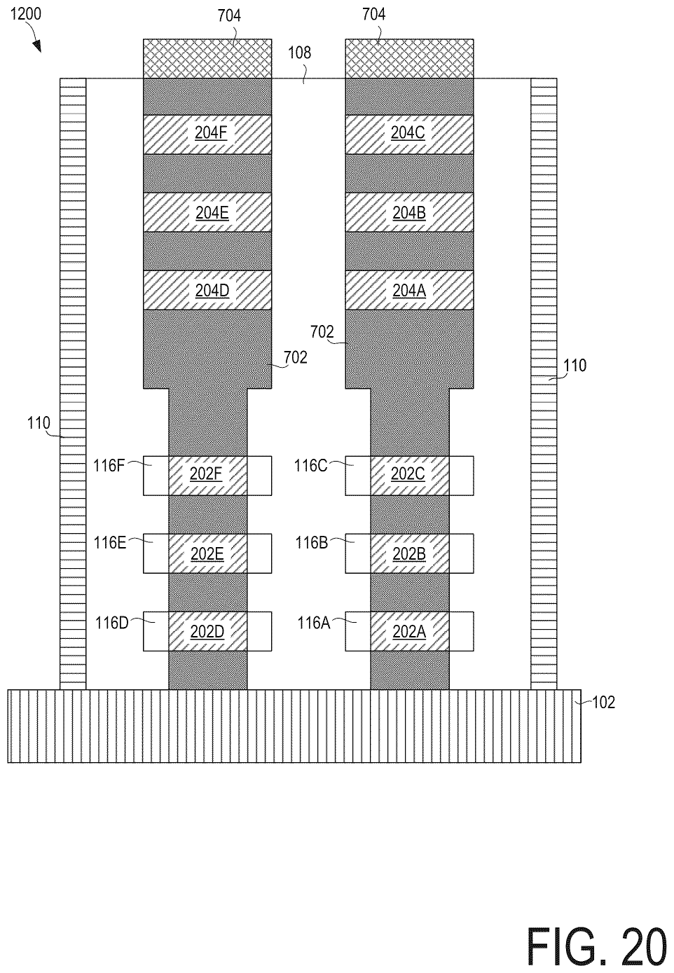

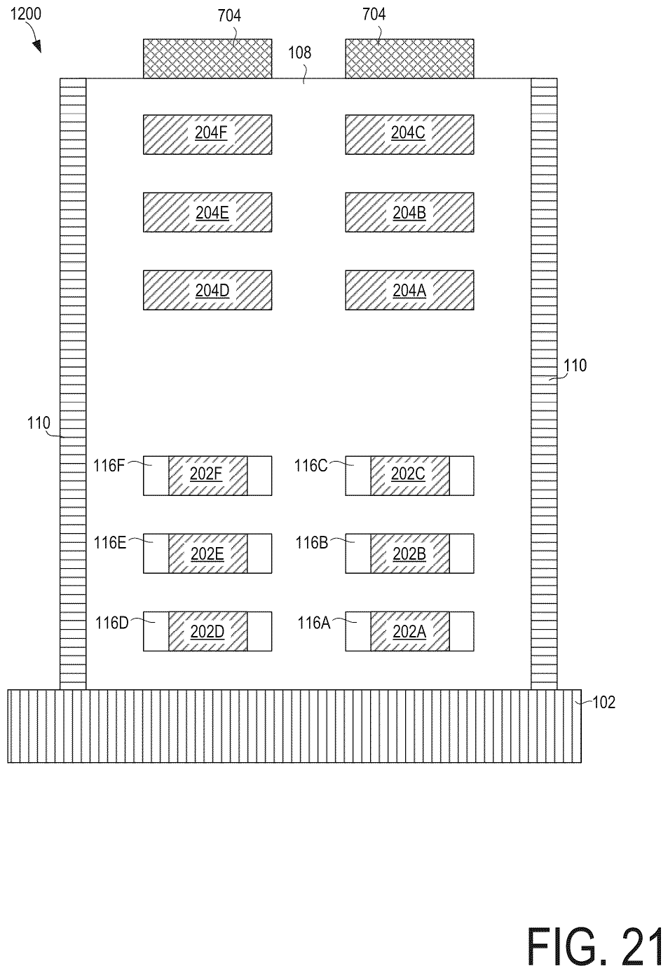

In block 1316, the liner 1702 is removed, as shown in FIG. 20. The channel regions 202A-F, 204A-F are released from the inter-nanoribbon layers 702 in block 1318, as shown in FIG. 21. In one embodiment, the inter-nanoribbon layers 702 are silicon-germanium and the source/drain regions 104A-F, 116A-F are silicon-germanium doped with, e.g., boron. As such, the etchant that removes the inter-nanoribbon layers 702 may also partially remove or narrow part of the source/drain regions 104A-F, 116A-F. Part of the source/drain regions 104A-F, 116A-F may be narrowed by, e.g., 20-90%. The source/drain regions 104A-F, 116A-F may be recessed from the dielectric spacer 108 by, e.g., 1-10 nanometers, depending on the embodiment.

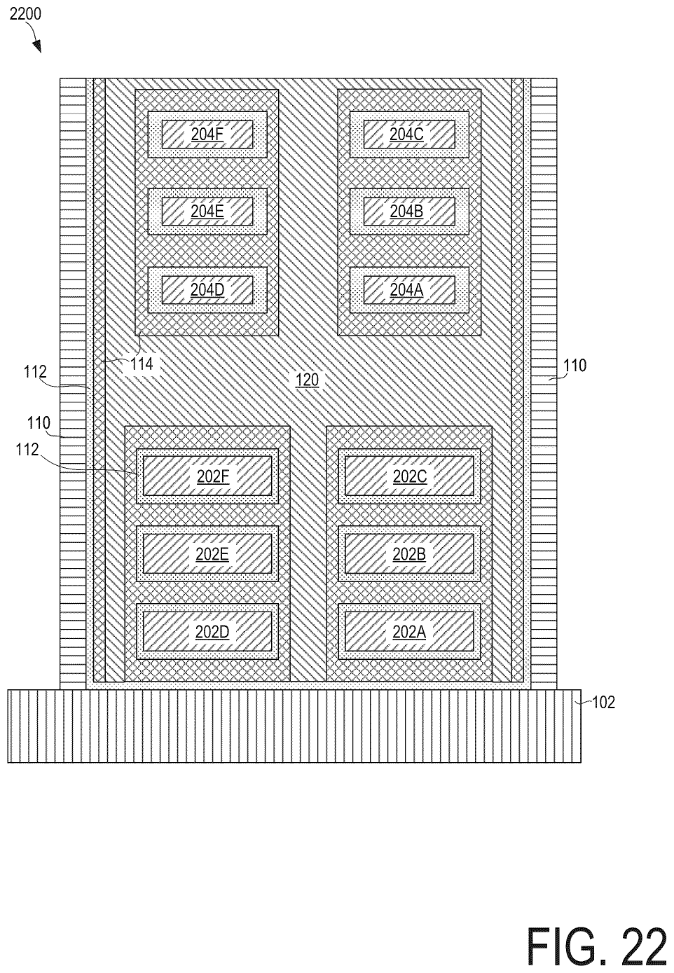

Referring now to FIG. 22, in one embodiment, one or more ribbon FETs 2200 are shown. The one or more ribbon FETs 2200 may be similar to the one or more FETs 100 described above, and similar components may have similar or the same labels. A description of the aspects of the one or more ribbon FETs 2200 that are similar or the same as the one or more ribbon FETs 100 will not be repeated in the interest of clarity. In the illustrative one or more ribbon FETs 2200, the channels 204A-F are thinner in the vertical direction as well as narrower than the channels 202A-F below them, as shown in FIG. 12.

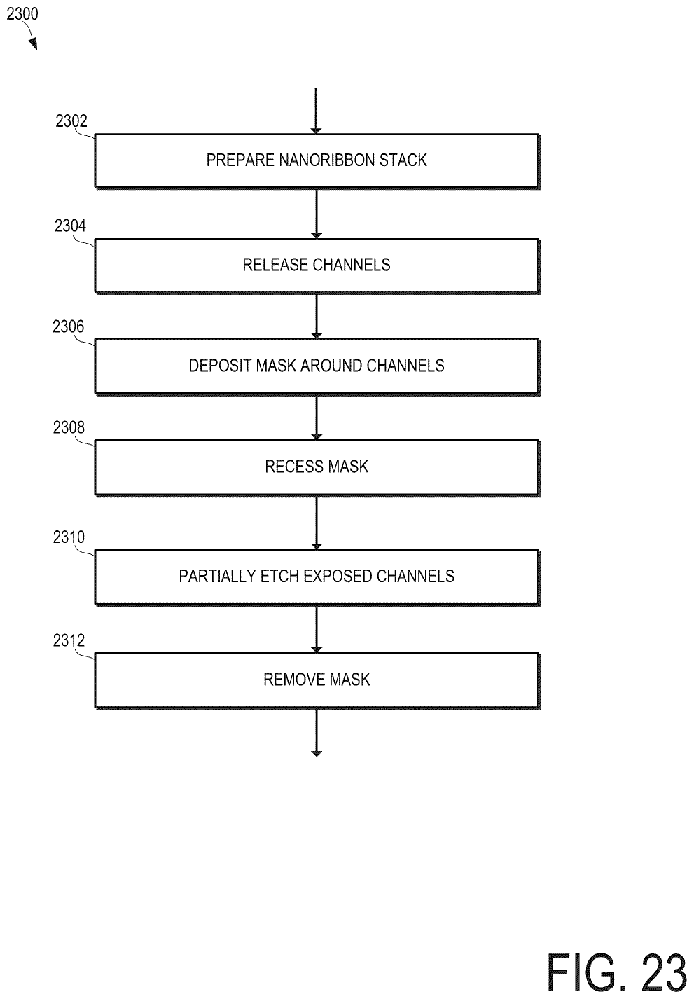

Referring now to FIG. 23, in one embodiment, a flowchart for a method 2300 for narrowing one or more channels of a transistor structure is shown. The method 2300 may be executed in a similar manner and using similar techniques as the method 600 above. In some cases, similar materials such as liners and masks may be used in the method 2300 in a similar manner as the method 600. The details of the techniques, materials, etc., of the method 600 will not be repeated in the interest of clarity.

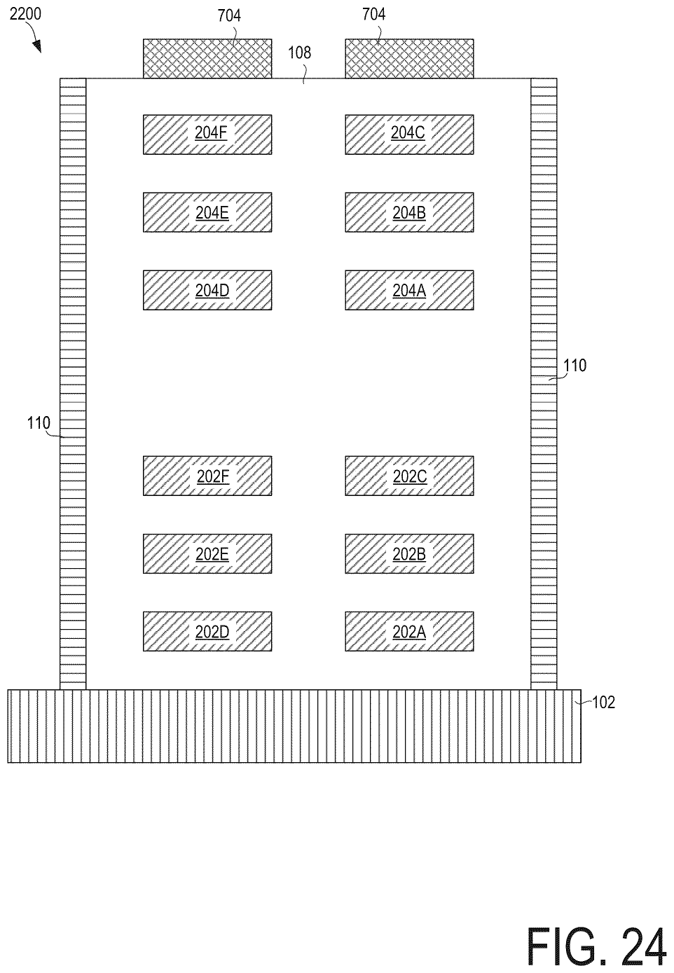

The method 2300 begins in block 2302, in which a stack of semiconductor nanoribbons 122 is prepared, including the source regions 104A-F, 106A-F, the drain regions 116A-F, 118A-F, the dielectric spacers 108, and the dielectric isolation layers 110. In block 2304, the stack of semiconductor nanoribbons 122 may be released (i.e., removing temporary material between the channel regions 202A-F, 204A-F that is present as part of forming the stack of semiconductor nanoribbons 122), as shown in FIG. 24.

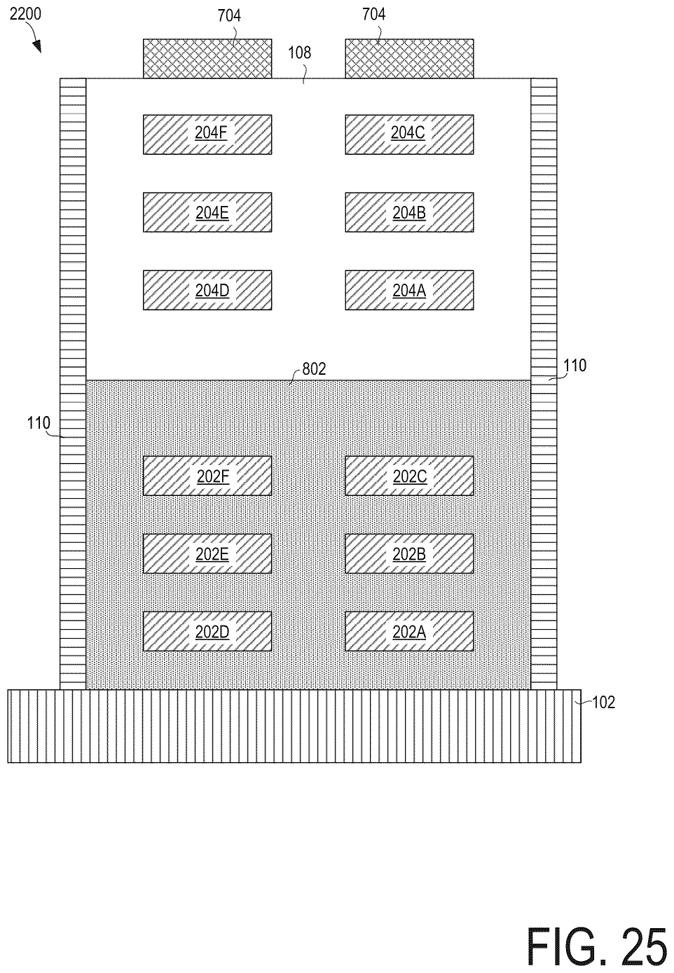

In block 2306, a mask 802 is applied. In block 2308, the mask 802 is recessed, exposing the channel regions 204A-204F, as shown in FIG. 25. In the illustrative embodiment, the mask 802 is a carbon hard mask. In other embodiments, the mask 802 may be a different material.

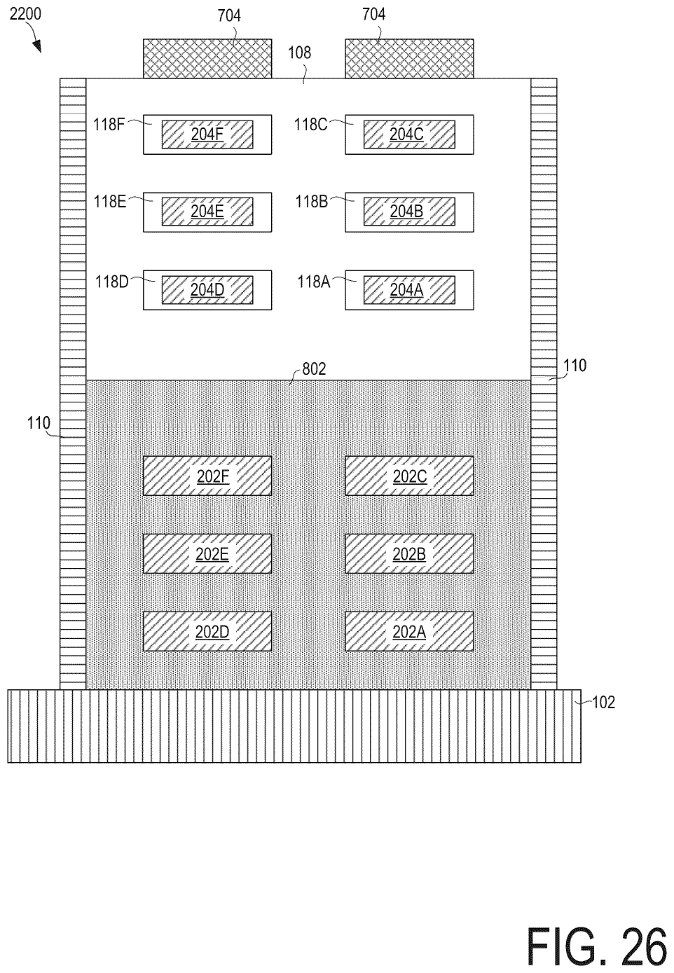

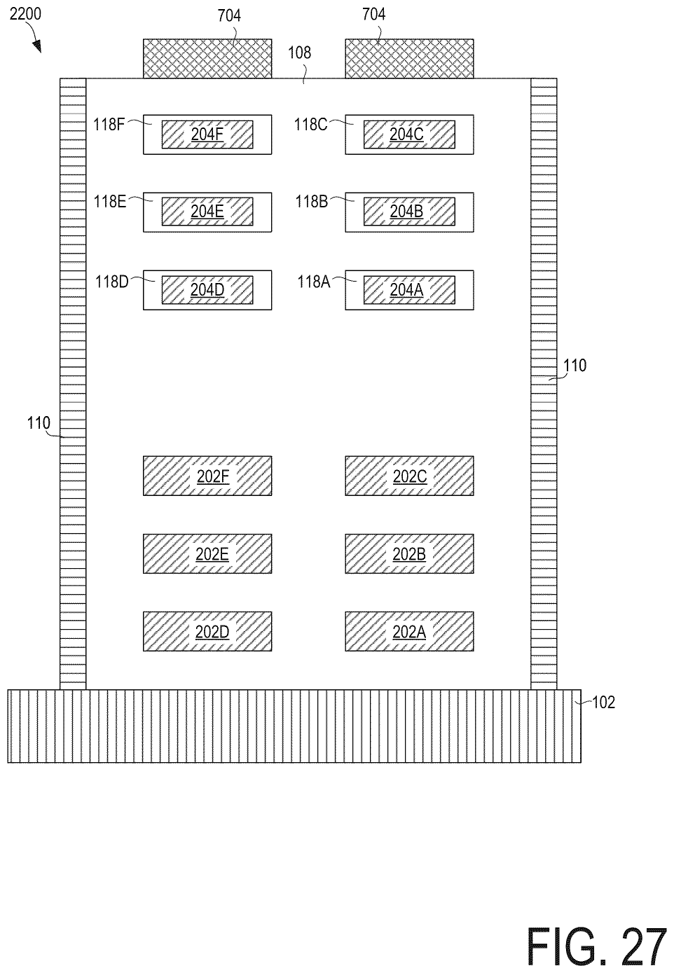

In block 2310, the channel regions 204A-204F are partially etched to narrow and thin the channel regions 204A-204F, as shown in FIG. 26. The channel regions 204A-204F may be narrower and thinned by any suitable amount, such as being 20-90% of the width and/or height of the channel regions 204A-204F. The mask 802 prevents the channel regions 202A-202F from being etched as well. The source regions 106A-F and drain regions 118A-F are partially exposed once the channels 204A-F are removed. Depending on the particular materials, dopants, etc., of the source regions 106A-F and drain regions 118A-F, part of the source regions 106A-F and/or drain regions 118A-F may be partially etched away as well, either at block 2310 or a later block or processing step. In block 2312, the mask 802 is removed, as shown in FIG. 27.

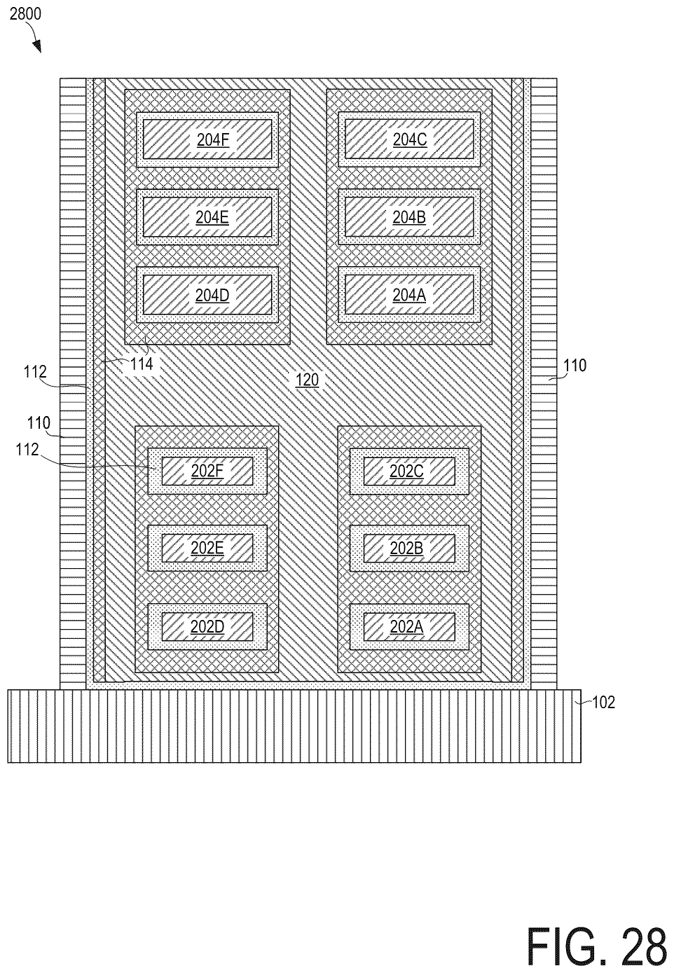

Referring now to FIG. 28, in one embodiment, one or more ribbon FETs 2800 are shown. The one or more ribbon FETs 2800 may be similar to the one or more FETs 100 described above, and similar components may have similar or the same labels. A description of the aspects of the one or more ribbon FETs 2800 that are similar or the same as the one or more ribbon FETs 100 will not be repeated in the interest of clarity. In the illustrative one or more ribbon FETs 2800, the channels 202A-F are thinner in the vertical direction as well as narrower than the channels 204A-F above them, as shown in FIG. 28.

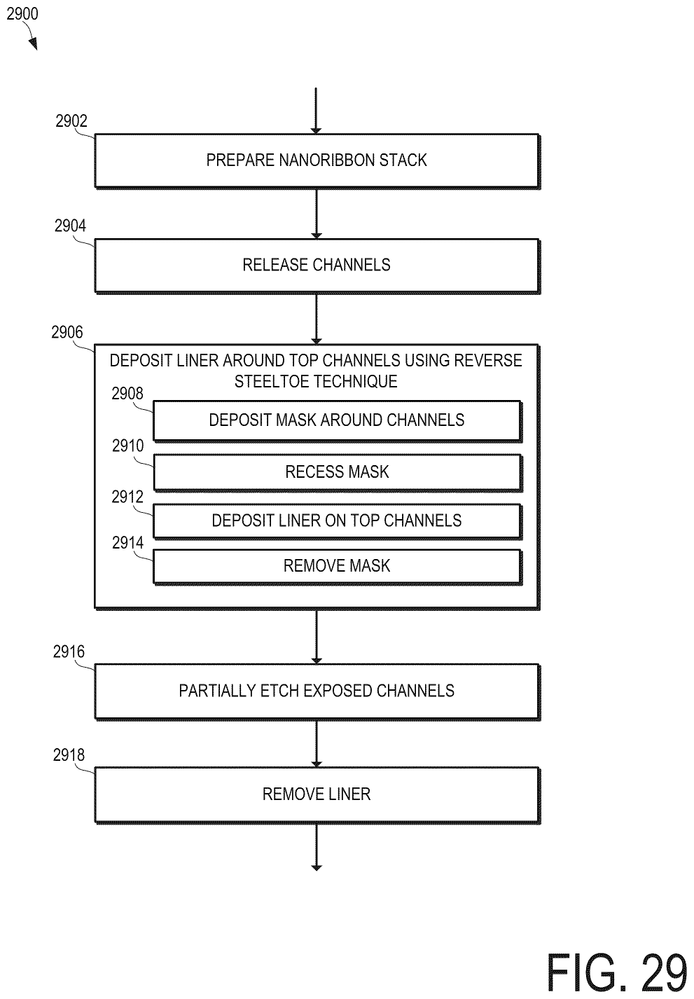

Referring now to FIG. 29, in one embodiment, a flowchart for a method 2900 for narrowing one or more channels of a transistor structure is shown. The method 2900 may be executed in a similar manner and using similar techniques as the method 600 above. In some cases, similar materials such as liners and masks may be used in the method 2900 in a similar manner as the method 600. The details of the techniques, materials, etc., of the method 600 will not be repeated in the interest of clarity.

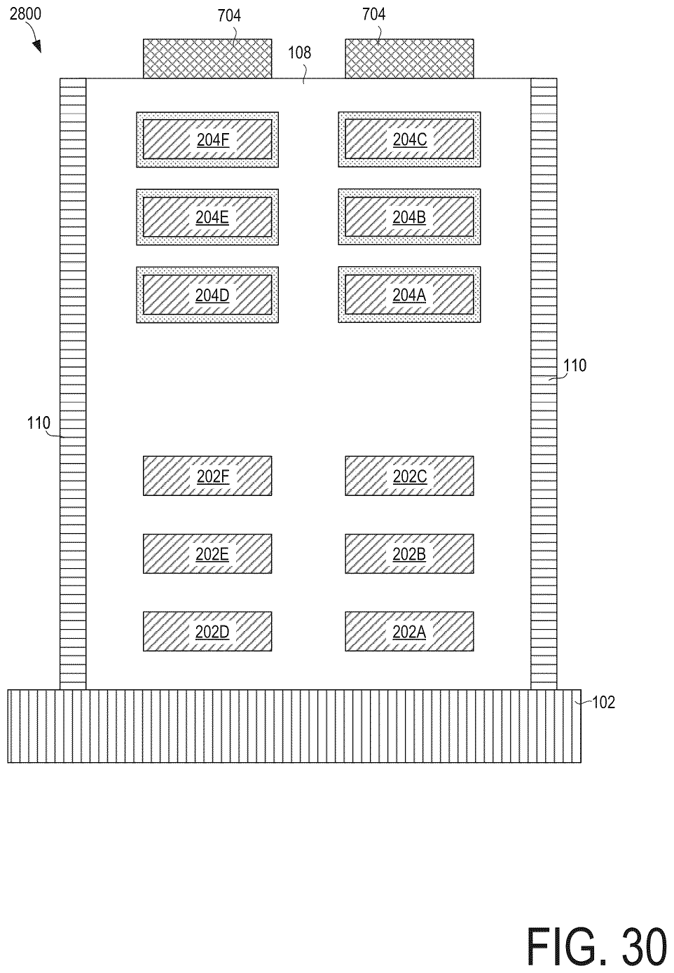

The method 2900 begins in block 2902, in which a stack of semiconductor nanoribbons 122 is prepared, including the source regions 104A-F, 106A-F, the drain regions 116A-F, 118A-F, the dielectric spacers 108, and the dielectric isolation layers 110. In block 2904, the stack of semiconductor nanoribbons 122 may be released (i.e., removing temporary material between the channel regions 202A-F, 204A-F that is present as part of forming the stack of semiconductor nanoribbons 122), as shown in FIG. 30.

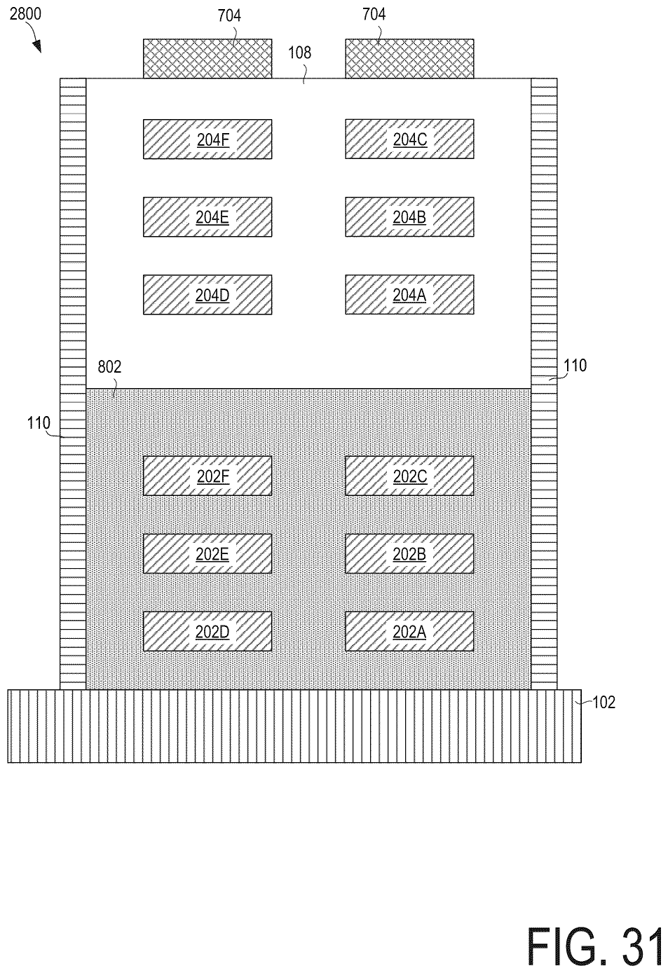

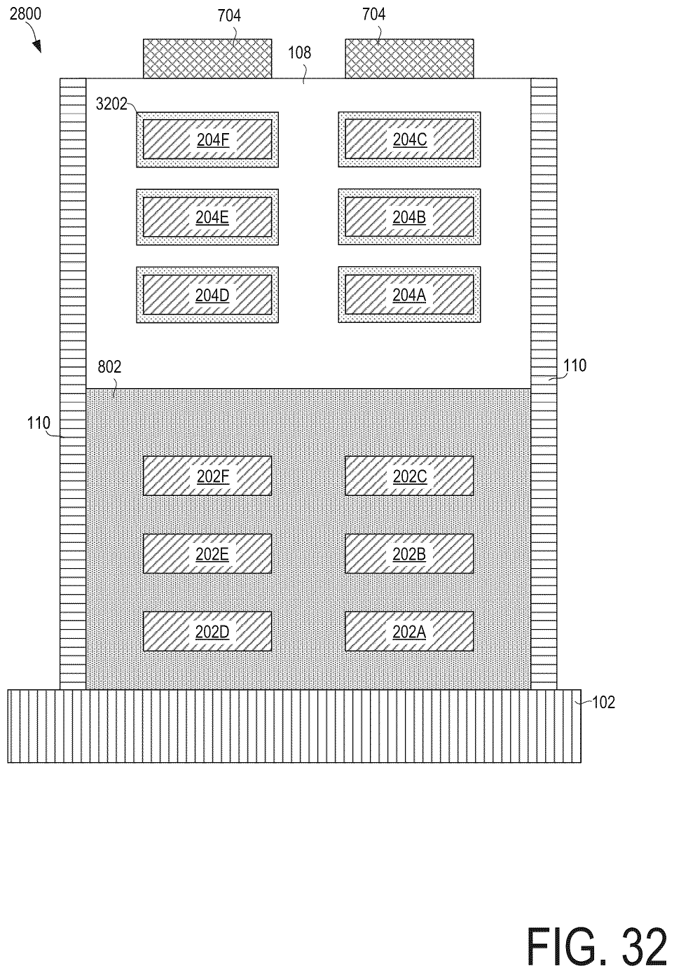

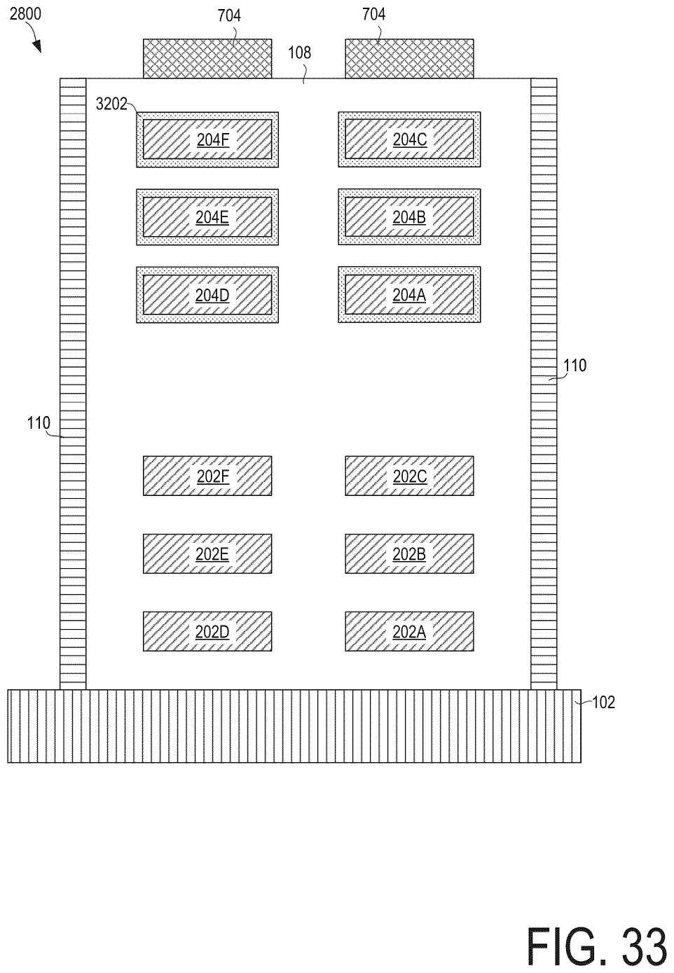

In block 2906, a liner 3202 is deposited around the channel regions 204A-F using a technique which may be referred to as a reverse steel toe technique. To do so, in block 2908, a mask 802 is deposited around the channel regions 202A-F, 204A-F. In block 2910, the mask 802 is then recessed to expose the channel regions 204A-204F, as shown in FIG. 31. In block 2912, the liner 3202 is then deposited on the top channel regions 204A-F, as shown in FIG. 32. In block 2914, the mask 802 is removed, leaving the liner 3202 behind, as shown in FIG. 33.

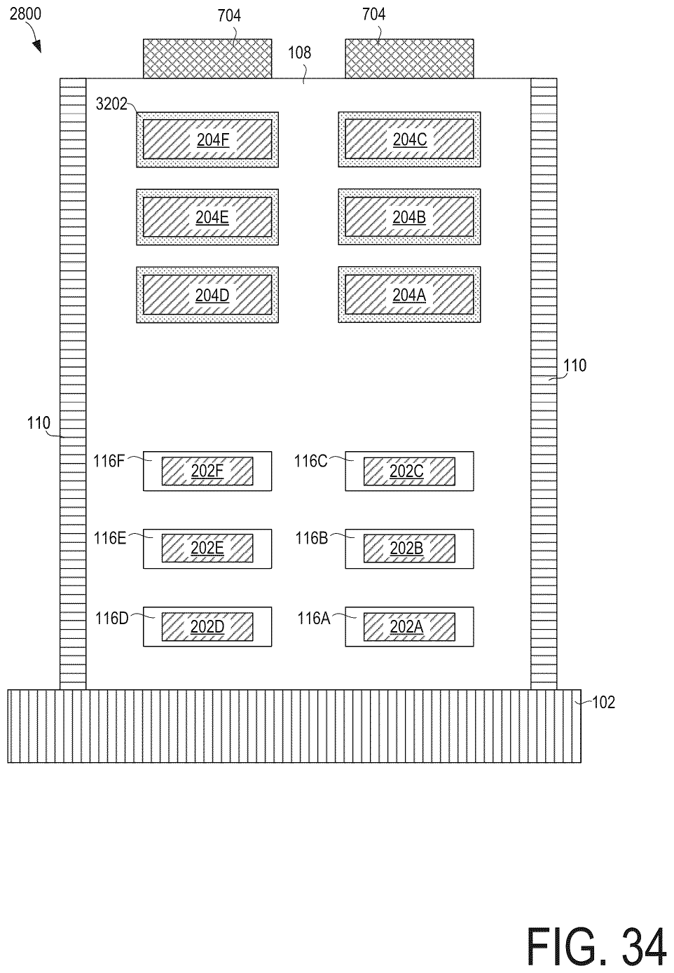

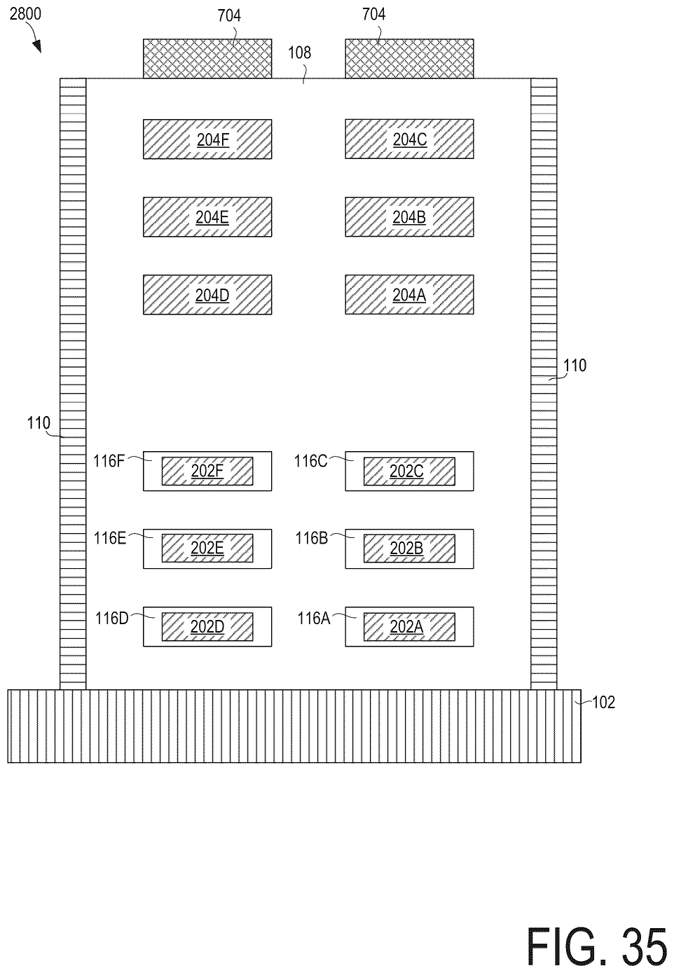

In block 2916, the channel regions 202A-202F are partially etched to narrow and thin the channel regions 202A-202F, as shown in FIG. 34. The channel regions 202A-202F may be narrower and thinned by any suitable amount, such as being 20-90% of the width and height of the channel regions 204A-204F. The liner 3202 prevents the channel regions 204A-204F from being etched as well. The source regions 104A-F and drain regions 116A-F are partially exposed once the channels 202A-F are removed. Depending on the particular materials, dopants, etc., of the source regions 104A-F and drain regions 116A-F, part of the source regions 104A-F and/or drain regions 116A-F may be partially etched away as well, either at block 2916 or a later block or processing step. In block 2918, the liner 3202 is removed, as shown in FIG. 35.

It should be appreciated that the embodiments described in detail above are merely some possible embodiments, and other embodiments are envisioned as well. For example, instead of narrowing and/or thinning all of channel regions 202A-F and/or 204A-D, only some of them, such as only channel regions 204C, 204F or only channel regions 202C, 202F may be narrowed and/or thinned.

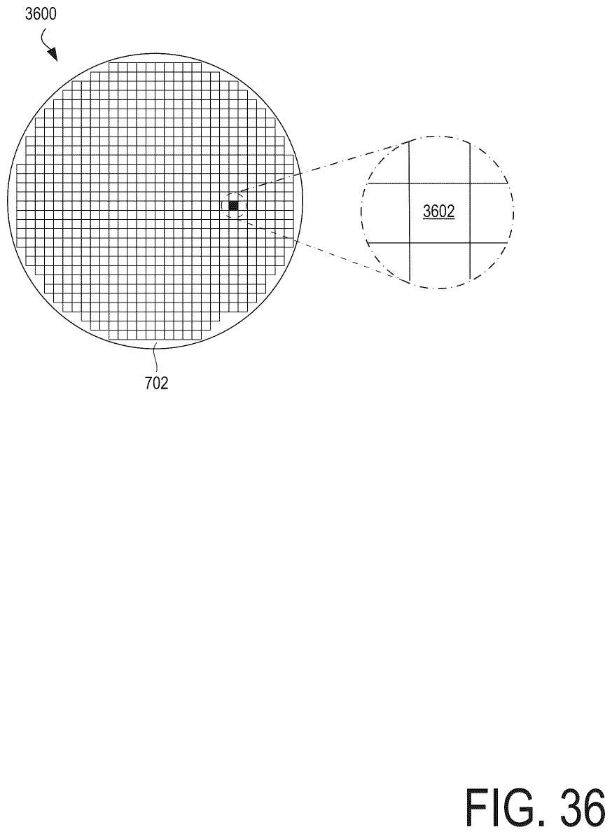

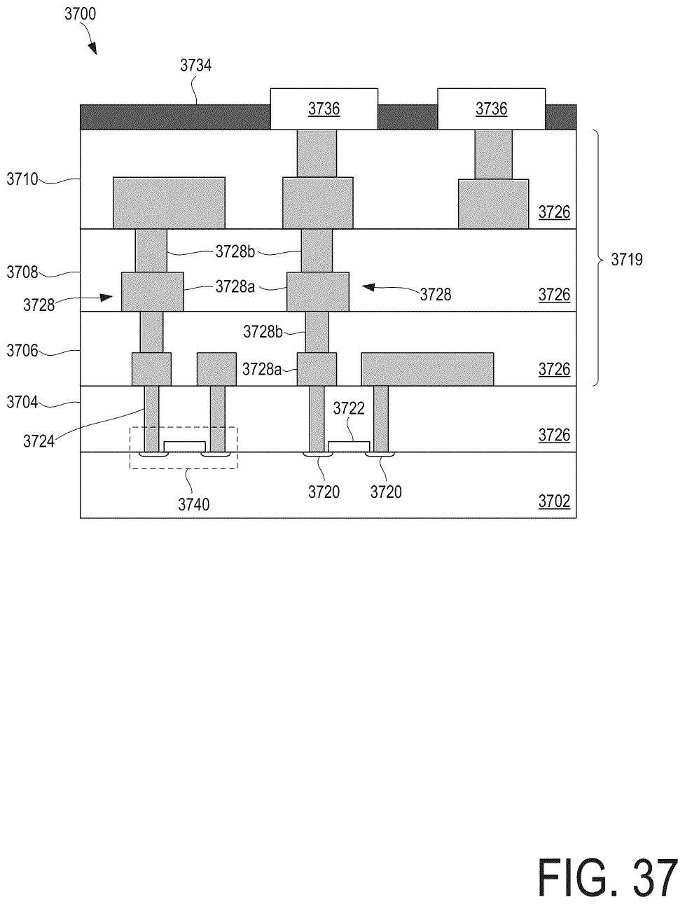

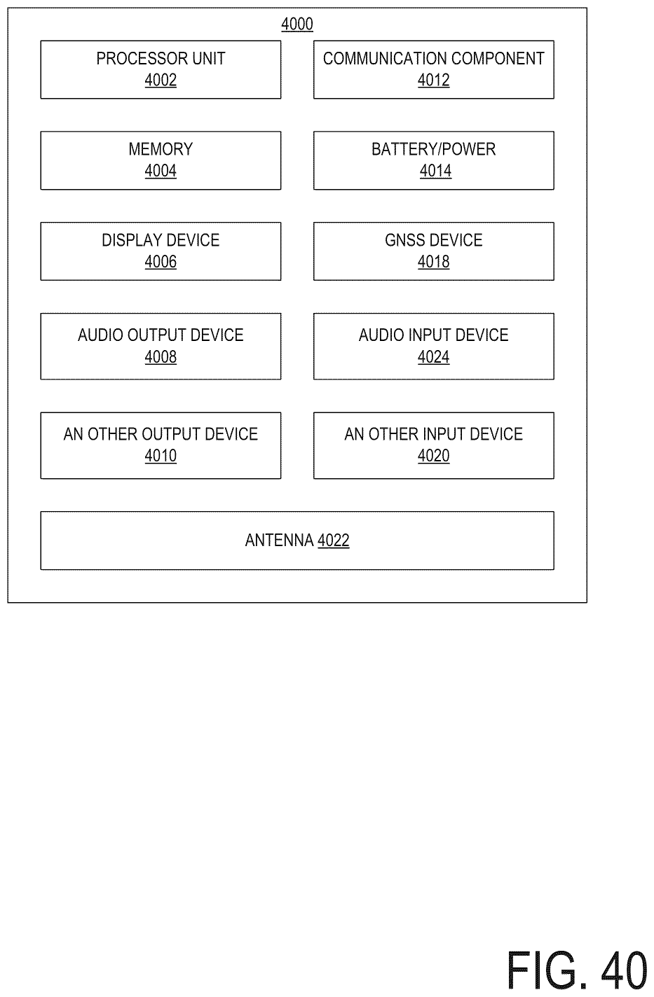

FIG. 36 is a top view of a wafer 3600 and dies 3602 that may include any of the one or more ribbon FETs 100, 1200, 2200, 2800 disclosed herein. The wafer 3600 may be composed of semiconductor material and may include one or more dies 3602 having integrated circuit structures formed on a surface of the wafer 3600. The individual dies 3602 may be a repeating unit of an integrated circuit product that includes any suitable integrated circuit. After the fabrication of the semiconductor product is complete, the wafer 3600 may undergo a singulation process in which the dies 3602 are separated from one another to provide discrete “chips” of the integrated circuit product. The die 3602 may include any of the one or more ribbon FETs 100, 1200, 2200, 2800 disclosed herein. The die 3602 may include one or more transistors (e.g., some of the transistors 3740 of FIG. 37, discussed below), supporting circuitry to route electrical signals to the transistors, passive components (e.g., signal traces, resistors, capacitors, or inductors), and/or any other integrated circuit components. In some embodiments, the wafer 3600 or the die 3602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 3602. For example, a memory array formed by multiple memory devices may be formed on a same die 3602 as a processor unit (e.g., the processor unit 4002 of FIG. 40) or other logic that is configured to store information in the memory devices or execute instructions stored in the memory array. Various ones of the one or more ribbon FETs 100, 1200, 2200, 2800 disclosed herein may be manufactured using a die-to-wafer assembly technique in which some dies are attached to a wafer 3600 that include others of the dies, and the wafer 3600 is subsequently singulated.

FIG. 37 is a cross-sectional side view of an integrated circuit device 3700 that may include in any of the one or more ribbon FETs 100, 1200, 2200, 2800 disclosed herein. One or more of the integrated circuit devices 3700 may be included in one or more dies 3602 (FIG. 36). The integrated circuit device 3700 may be formed on a die substrate 3702 (e.g., the wafer 3600 of FIG. 36) and may be included in a die (e.g., the die 3602 of FIG. 36). The die substrate 3702 may be a semiconductor substrate composed of semiconductor material systems including, for example, n-type or p-type materials systems (or a combination of both). The die substrate 3702 may include, for example, a crystalline substrate formed using a bulk silicon or a silicon-on-insulator (SOI) substructure. In some embodiments, the die substrate 3702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 3702. Although a few examples of materials from which the die substrate 3702 may be formed are described here, any material that may serve as a foundation for an integrated circuit device 3700 may be used. The die substrate 3702 may be part of a singulated die (e.g., the dies 3602 of FIG. 36) or a wafer (e.g., the wafer 3600 of FIG. 36).

The integrated circuit device 3700 may include one or more device layers 3704 disposed on the die substrate 3702. The device layer 3704 may include features of one or more transistors 3740 (e.g., metal oxide semiconductor field-effect transistors (MOSFETs)) formed on the die substrate 3702. The transistors 3740 may include, for example, one or more source and/or drain (S/D) regions 3720, a gate 3722 to control current flow between the S/D regions 3720, and one or more S/D contacts 3724 to route electrical signals to/from the S/D regions 3720. The transistors 3740 may include additional features not depicted for the sake of clarity, such as device isolation regions, gate contacts, and the like. The transistors 3740 are not limited to the type and configuration depicted in FIG. 37 and may include a wide variety of other types and configurations such as, for example, planar transistors, non-planar transistors, or a combination of both. Non-planar transistors may include NanoribbonFET transistors, such as double-gate transistors or tri-gate transistors, and wrap-around or all-around gate transistors, such as nanoribbon, nanosheet, or nanowire transistors.

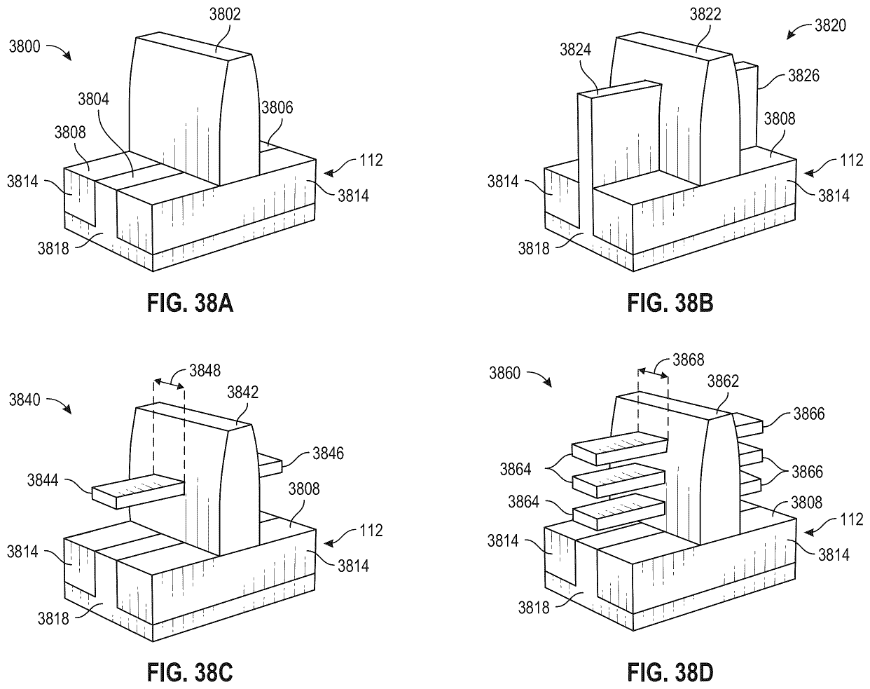

FIGS. 38A-38D are simplified perspective views of example planar, NanoribbonFET, gate-all-around, and stacked gate-all-around transistors. The transistors illustrated in FIGS. 38A-38D are formed on a substrate 3816 having a surface 3808. Isolation regions 3814 separate the source and drain regions of the transistors from other transistors and from a bulk region 3818 of the substrate 3816.

FIG. 38A is a perspective view of an example planar transistor 3800 comprising a gate 3802 that controls current flow between a source region 3804 and a drain region 3806. The transistor 3800 is planar in that the source region 3804 and the drain region 3806 are planar with respect to the substrate surface 3808.

FIG. 38B is a perspective view of an example NanoribbonFET transistor 3820 comprising a gate 3822 that controls current flow between a source region 3824 and a drain region 3826. The transistor 3820 is non-planar in that the source region 3824 and the drain region 3826 comprise “nanoribbons” that extend upwards from the substrate surface 3828. As the gate 3822 encompasses three sides of the semiconductor nanoribbon that extends from the source region 3824 to the drain region 3826, the transistor 3820 can be considered a tri-gate transistor. FIG. 38B illustrates one S/D nanoribbon extending through the gate 3822, but multiple S/D nanoribbons can extend through the gate of a NanoribbonFET transistor.

FIG. 38C is a perspective view of a gate-all-around (GAA) transistor 3840 comprising a gate 3842 that controls current flow between a source region 3844 and a drain region 3846. The transistor 3840 is non-planar in that the source region 3844 and the drain region 3846 are elevated from the substrate surface 3828.

FIG. 38D is a perspective view of a GAA transistor 3860 comprising a gate 3862 that controls current flow between multiple elevated source regions 3864 and multiple elevated drain regions 3866. The transistor 3860 is a stacked GAA transistor as the gate controls the flow of current between multiple elevated S/D regions stacked on top of each other. The transistors 3840 and 3860 are considered gate-all-around transistors as the gates encompass all sides of the semiconductor portions that extends from the source regions to the drain regions. The transistors 3840 and 3860 can alternatively be referred to as nanowire, nanosheet, or nanoribbon transistors depending on the width (e.g., widths 3848 and 3868 of transistors 3840 and 3860, respectively) of the semiconductor portions extending through the gate.

Returning to FIG. 37, a transistor 3740 may include a gate 3722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 3740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 3740 along the source-channel-drain direction, the gate electrode may consist of a U-shaped structure that includes a bottom portion substantially parallel to the surface of the die substrate 3702 and two sidewall portions that are substantially perpendicular to the top surface of the die substrate 3702. In other embodiments, at least one of the metal layers that form the gate electrode may simply be a planar layer that is substantially parallel to the top surface of the die substrate 3702 and does not include sidewall portions substantially perpendicular to the top surface of the die substrate 3702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 3720 may be formed within the die substrate 3702 adjacent to the gate 3722 of individual transistors 3740. The S/D regions 3720 may be formed using an implantation/diffusion process or an etching/deposition process, for example. In the former process, dopants such as boron, aluminum, antimony, phosphorous, or arsenic may be ion-implanted into the die substrate 3702 to form the S/D regions 3720. An annealing process that activates the dopants and causes them to diffuse farther into the die substrate 3702 may follow the ion-implantation process. In the latter process, the die substrate 3702 may first be etched to form recesses at the locations of the S/D regions 3720. An epitaxial deposition process may then be carried out to fill the recesses with material that is used to fabricate the S/D regions 3720. In some implementations, the S/D regions 3720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 3720 may be formed using one or more alternate semiconductor materials such as germanium or a group III-V material or alloy. In further embodiments, one or more layers of metal and/or metal alloys may be used to form the S/D regions 3720.

Electrical signals, such as power and/or input/output (I/O) signals, may be routed to and/or from the devices (e.g., transistors 3740) of the device layer 3704 through one or more interconnect layers disposed on the device layer 3704 (illustrated in FIG. 37 as interconnect layers 3706-3710). For example, electrically conductive features of the device layer 3704 (e.g., the gate 3722 and the S/D contacts 3724) may be electrically coupled with the interconnect structures 3728 of the interconnect layers 3706-3710. The one or more interconnect layers 3706-3710 may form a metallization stack (also referred to as an “ILD stack”) 3719 of the integrated circuit device 3700.

The interconnect structures 3728 may be arranged within the interconnect layers 3706-3710 to route electrical signals according to a wide variety of designs; in particular, the arrangement is not limited to the particular configuration of interconnect structures 3728 depicted in FIG. 37. Although a particular number of interconnect layers 3706-3710 is depicted in FIG. 37, embodiments of the present disclosure include integrated circuit devices having more or fewer interconnect layers than depicted.

In some embodiments, the interconnect structures 3728 may include lines 3728a and/or vias 3728b filled with an electrically conductive material such as a metal. The lines 3728a may be arranged to route electrical signals in a direction of a plane that is substantially parallel with a surface of the die substrate 3702 upon which the device layer 3704 is formed. For example, the lines 3728a may route electrical signals in a direction in and out of the page and/or in a direction across the page. The vias 3728b may be arranged to route electrical signals in a direction of a plane that is substantially perpendicular to the surface of the die substrate 3702 upon which the device layer 3704 is formed. In some embodiments, the vias 3728b may electrically couple lines 3728a of different interconnect layers 3706-3710 together.

The interconnect layers 3706-3710 may include a dielectric material 3726 disposed between the interconnect structures 3728, as shown in FIG. 37. In some embodiments, dielectric material 3726 disposed between the interconnect structures 3728 in different ones of the interconnect layers 3706-3710 may have different compositions; in other embodiments, the composition of the dielectric material 3726 between different interconnect layers 3706-3710 may be the same. The device layer 3704 may include a dielectric material 3726 disposed between the transistors 3740 and a bottom layer of the metallization stack as well. The dielectric material 3726 included in the device layer 3704 may have a different composition than the dielectric material 3726 included in the interconnect layers 3706-3710; in other embodiments, the composition of the dielectric material 3726 in the device layer 3704 may be the same as a dielectric material 3726 included in any one of the interconnect layers 3706-3710.

A first interconnect layer 3706 (referred to as Metal 1 or “M1”) may be formed directly on the device layer 3704. In some embodiments, the first interconnect layer 3706 may include lines 3728a and/or vias 3728b, as shown. The lines 3728a of the first interconnect layer 3706 may be coupled with contacts (e.g., the S/D contacts 3724) of the device layer 3704. The vias 3728b of the first interconnect layer 3706 may be coupled with the lines 3728a of a second interconnect layer 3708.

The second interconnect layer 3708 (referred to as Metal 2 or “M2”) may be formed directly on the first interconnect layer 3706. In some embodiments, the second interconnect layer 3708 may include via 3728b to couple the lines 3728 of the second interconnect layer 3708 with the lines 3728a of a third interconnect layer 3710. Although the lines 3728a and the vias 3728b are structurally delineated with a line within individual interconnect layers for the sake of clarity, the lines 3728a and the vias 3728b may be structurally and/or materially contiguous (e.g., simultaneously filled during a dual-damascene process) in some embodiments.

The third interconnect layer 3710 (referred to as Metal 3 or “M3”) (and additional interconnect layers, as desired) may be formed in succession on the second interconnect layer 3708 according to similar techniques and configurations described in connection with the second interconnect layer 3708 or the first interconnect layer 3706. In some embodiments, the interconnect layers that are “higher up” in the metallization stack 3719 in the integrated circuit device 3700 (i.e., farther away from the device layer 3704) may be thicker that the interconnect layers that are lower in the metallization stack 3719, with lines 3728a and vias 3728b in the higher interconnect layers being thicker than those in the lower interconnect layers.

The integrated circuit device 3700 may include a solder resist material 3734 (e.g., polyimide or similar material) and one or more conductive contacts 3736 formed on the interconnect layers 3706-3710. In FIG. 37, the conductive contacts 3736 are illustrated as taking the form of bond pads. The conductive contacts 3736 may be electrically coupled with the interconnect structures 3728 and configured to route the electrical signals of the transistor(s) 3740 to external devices. For example, solder bonds may be formed on the one or more conductive contacts 3736 to mechanically and/or electrically couple an integrated circuit die including the integrated circuit device 3700 with another component (e.g., a printed circuit board). The integrated circuit device 3700 may include additional or alternate structures to route the electrical signals from the interconnect layers 3706-3710; for example, the conductive contacts 3736 may include other analogous features (e.g., posts) that route the electrical signals to external components.

In some embodiments in which the integrated circuit device 3700 is a double-sided die, the integrated circuit device 3700 may include another metallization stack (not shown) on the opposite side of the device layer(s) 3704. This metallization stack may include multiple interconnect layers as discussed above with reference to the interconnect layers 3706-3710, to provide conductive pathways (e.g., including conductive lines and vias) between the device layer(s) 3704 and additional conductive contacts (not shown) on the opposite side of the integrated circuit device 3700 from the conductive contacts 3736.

In other embodiments in which the integrated circuit device 3700 is a double-sided die, the integrated circuit device 3700 may include one or more through silicon vias (TSVs) through the die substrate 3702; these TSVs may make contact with the device layer(s) 3704, and may provide conductive pathways between the device layer(s) 3704 and additional conductive contacts (not shown) on the opposite side of the integrated circuit device 3700 from the conductive contacts 3736. In some embodiments, TSVs extending through the substrate can be used for routing power and ground signals from conductive contacts on the opposite side of the integrated circuit device 3700 from the conductive contacts 3736 to the transistors 3740 and any other components integrated into the die 3700, and the metallization stack 3719 can be used to route I/O signals from the conductive contacts 3736 to transistors 3740 and any other components integrated into the die 3700.

Multiple integrated circuit devices 3700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be nanoribbone-pitch solder bumps (microbumps).

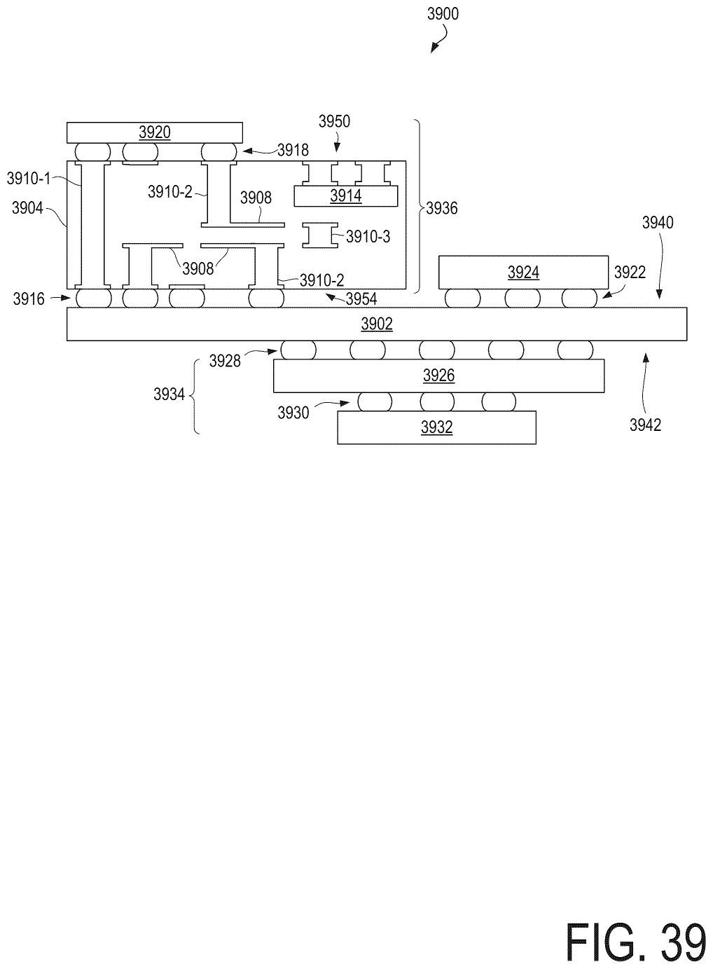

FIG. 39 is a cross-sectional side view of an integrated circuit device assembly 3900 that may include any of the one or more ribbon FETs 100, 1200, 2200, 2800 disclosed herein. The integrated circuit device assembly 3900 includes a number of components disposed on a circuit board 3902 (which may be a motherboard, system board, mainboard, etc.). The integrated circuit device assembly 3900 includes components disposed on a first face 3940 of the circuit board 3902 and an opposing second face 3942 of the circuit board 3902; generally, components may be disposed on one or both faces 3940 and 3942.

In some embodiments, the circuit board 3902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 3902. In other embodiments, the circuit board 3902 may be a non-PCB substrate. The integrated circuit device assembly 3900 illustrated in FIG. 39 includes a package-on-interposer structure 3936 coupled to the first face 3940 of the circuit board 3902 by coupling components 3916. The coupling components 3916 may electrically and mechanically couple the package-on-interposer structure 3936 to the circuit board 3902, and may include solder balls (as shown in FIG. 39), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 3936 may include an integrated circuit component 3920 coupled to an interposer 3904 by coupling components 3918. The coupling components 3918 may take any suitable form for the application, such as the forms discussed above with reference to the coupling components 3916. Although a single integrated circuit component 3920 is shown in FIG. 39, multiple integrated circuit components may be coupled to the interposer 3904; indeed, additional interposers may be coupled to the interposer 3904. The interposer 3904 may provide an intervening substrate used to bridge the circuit board 3902 and the integrated circuit component 3920.

The integrated circuit component 3920 may be a packaged or unpacked integrated circuit product that includes one or more integrated circuit dies (e.g., the die 3602 of FIG. 36, the integrated circuit device 3700 of FIG. 37) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 3920, a single monolithic integrated circuit die comprises solder bumps attached to contacts on the die. The solder bumps allow the die to be directly attached to the interposer 3904. The integrated circuit component 3920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 3920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 3920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 3920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 3904 may spread connections to a wider pitch or reroute a connection to a different connection. For example, the interposer 3904 may couple the integrated circuit component 3920 to a set of ball grid array (BGA) conductive contacts of the coupling components 3916 for coupling to the circuit board 3902. In the embodiment illustrated in FIG. 39, the integrated circuit component 3920 and the circuit board 3902 are attached to opposing sides of the interposer 3904; in other embodiments, the integrated circuit component 3920 and the circuit board 3902 may be attached to a same side of the interposer 3904. In some embodiments, three or more components may be interconnected by way of the interposer 3904.

In some embodiments, the interposer 3904 may be formed as a PCB, including multiple metal layers separated from one another by layers of dielectric material and interconnected by electrically conductive vias. In some embodiments, the interposer 3904 may be formed of an epoxy resin, a fiberglass-reinforced epoxy resin, an epoxy resin with inorganic fillers, a ceramic material, or a polymer material such as polyimide. In some embodiments, the interposer 3904 may be formed of alternate rigid or flexible materials that may include the same materials described above for use in a semiconductor substrate, such as silicon, germanium, and other group III-V and group IV materials. The interposer 3904 may include metal interconnects 3908 and vias 3910, including but not limited to through hole vias 3910-1 (that extend from a first face 3950 of the interposer 3904 to a second face 3954 of the interposer 3904), blind vias 3910-2 (that extend from the first or second faces 3950 or 3954 of the interposer 3904 to an internal metal layer), and buried vias 3910-3 (that connect internal metal layers).

In some embodiments, the interposer 3904 can comprise a silicon interposer. Through silicon vias (TSV) extending through the silicon interposer can connect connections on a first face of a silicon interposer to an opposing second face of the silicon interposer. In some embodiments, an interposer 3904 comprising a silicon interposer can further comprise one or more routing layers to route connections on a first face of the interposer 3904 to an opposing second face of the interposer 3904.

The interposer 3904 may further include embedded devices 3914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3904. The package-on-interposer structure 3936 may take the form of any of the package-on-interposer structures known in the art.

The integrated circuit device assembly 3900 may include an integrated circuit component 3924 coupled to the first face 3940 of the circuit board 3902 by coupling components 3922. The coupling components 3922 may take the form of any of the embodiments discussed above with reference to the coupling components 3916, and the integrated circuit component 3924 may take the form of any of the embodiments discussed above with reference to the integrated circuit component 3920.

The integrated circuit device assembly 3900 illustrated in FIG. 39 includes a package-on-package structure 3934 coupled to the second face 3942 of the circuit board 3902 by coupling components 3928. The package-on-package structure 3934 may include an integrated circuit component 3926 and an integrated circuit component 3932 coupled together by coupling components 3930 such that the integrated circuit component 3926 is disposed between the circuit board 3902 and the integrated circuit component 3932. The coupling components 3928 and 3930 may take the form of any of the embodiments of the coupling components 3916 discussed above, and the integrated circuit components 3926 and 3932 may take the form of any of the embodiments of the integrated circuit component 3920 discussed above. The package-on-package structure 3934 may be configured in accordance with any of the package-on-package structures known in the art.

FIG. 40 is a block diagram of an example electrical device 4000 that may include one or more of the one or more ribbon FETs 100, 1200, 2200, 2800 disclosed herein. For example, any suitable ones of the components of the electrical device 4000 may include one or more of the integrated circuit device assemblies 3900, integrated circuit components 3920, integrated circuit devices 3700, or integrated circuit dies 3602 disclosed herein. A number of components are illustrated in FIG. 40 as included in the electrical device 4000, but any one or more of these components may be omitted or duplicated, as suitable for the application. In some embodiments, some or all of the components included in the electrical device 4000 may be attached to one or more motherboards mainboards, or system boards. In some embodiments, one or more of these components are fabricated onto a single system-on-a-chip (SoC) die.

Additionally, in various embodiments, the electrical device 4000 may not include one or more of the components illustrated in FIG. 40, but the electrical device 4000 may include interface circuitry for coupling to the one or more components. For example, the electrical device 4000 may not include a display device 4006, but may include display device interface circuitry (e.g., a connector and driver circuitry) to which a display device 4006 may be coupled. In another set of examples, the electrical device 4000 may not include an audio input device 4024 or an audio output device 4008, but may include audio input or output device interface circuitry (e.g., connectors and supporting circuitry) to which an audio input device 4024 or audio output device 4008 may be coupled.

The electrical device 4000 may include one or more processor units 4002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 4002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 4000 may include a memory 4004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 4004 may include memory that is located on the same integrated circuit die as the processor unit 4002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 4000 can comprise one or more processor units 4002 that are heterogeneous or asymmetric to another processor unit 4002 in the electrical device 4000. There can be a variety of differences between the processing units 4002 in a system in terms of a spectrum of metrics of merit including architectural, microarchitectural, thermal, power consumption characteristics, and the like. These differences can effectively manifest themselves as asymmetry and heterogeneity among the processor units 4002 in the electrical device 4000.

In some embodiments, the electrical device 4000 may include a communication component 4012 (e.g., one or more communication components). For example, the communication component 4012 can manage wireless communications for the transfer of data to and from the electrical device 4000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 4012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 4012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 4012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 4012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 4012 may operate in accordance with other wireless protocols in other embodiments. The electrical device 4000 may include an antenna 4022 to facilitate wireless communications and/or to receive other wireless communications (such as AM or FM radio transmissions).

In some embodiments, the communication component 4012 may manage wired communications, such as electrical, optical, or any other suitable communication protocols (e.g., IEEE 802.3 Ethernet standards). As noted above, the communication component 4012 may include multiple communication components. For instance, a first communication component 4012 may be dedicated to shorter-range wireless communications such as Wi-Fi or Bluetooth, and a second communication component 4012 may be dedicated to longer-range wireless communications such as global positioning system (GPS), EDGE, GPRS, CDMA, WiMAX, LTE, EV-DO, or others. In some embodiments, a first communication component 4012 may be dedicated to wireless communications, and a second communication component 4012 may be dedicated to wired communications.

The electrical device 4000 may include battery/power circuitry 4014. The battery/power circuitry 4014 may include one or more energy storage devices (e.g., batteries or capacitors) and/or circuitry for coupling components of the electrical device 4000 to an energy source separate from the electrical device 4000 (e.g., AC line power).

The electrical device 4000 may include a display device 4006 (or corresponding interface circuitry, as discussed above). The display device 4006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 4000 may include an audio output device 4008 (or corresponding interface circuitry, as discussed above). The audio output device 4008 may include any embedded or wired or wirelessly connected external device that generates an audible indicator, such speakers, headsets, or earbuds.

The electrical device 4000 may include an audio input device 4024 (or corresponding interface circuitry, as discussed above). The audio input device 4024 may include any embedded or wired or wirelessly connected device that generates a signal representative of a sound, such as microphones, microphone arrays, or digital instruments (e.g., instruments having a musical instrument digital interface (MIDI) output). The electrical device 4000 may include a Global Navigation Satellite System (GNSS) device 4018 (or corresponding interface circuitry, as discussed above), such as a Global Positioning System (GPS) device. The GNSS device 4018 may be in communication with a satellite-based system and may determine a geolocation of the electrical device 4000 based on information received from one or more GNSS satellites, as known in the art.

The electrical device 4000 may include an other output device 4010 (or corresponding interface circuitry, as discussed above). Examples of the other output device 4010 may include an audio codec, a video codec, a printer, a wired or wireless transmitter for providing information to other devices, or an additional storage device.

The electrical device 4000 may include an other input device 4020 (or corresponding interface circuitry, as discussed above). Examples of the other input device 4020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 4000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 4000 may be any other electronic device that processes data. In some embodiments, the electrical device 4000 may comprise multiple discrete physical components. Given the range of devices that the electrical device 4000 can be manifested as in various embodiments, in some embodiments, the electrical device 4000 can be referred to as a computing device or a computing system.

### Examples

Illustrative examples of the technologies disclosed herein are provided below. An embodiment of the technologies may include any one or more, and any combination of, the examples described below.

Example 1 includes a device comprising a substrate; one or more transistors on a surface of the substrate, the one or more transistors comprising a semiconductor nanoribbon comprising a first source or drain region; a channel region; and a second source or drain region, wherein the channel region has a length extending from the first source or drain region to the second source or drain region, wherein the channel region has a width perpendicular to the length and parallel to the surface of the substrate, wherein the width of the channel region is at least 20% less than a width of the first source or drain region and a width of the second source or drain region.

Example 2 includes the subject matter of Example 1, and wherein the channel region has a thickness perpendicular to its width and length, wherein the channel region has a thickness that is less than 80% of a thickness of the first source or drain region.

Example 3 includes the subject matter of any of Examples 1 and 2, and wherein the one or more transistors comprise a plurality of semiconductor nanoribbons, wherein the plurality of semiconductor nanoribbons are stacked on top of each other above the substrate, the plurality of semiconductor nanoribbons comprising the semiconductor nanoribbon; and a second semiconductor nanoribbon comprising a third source or drain region; a second channel region; and a fourth source or drain region, wherein the second channel region has a length extending from the second source or drain region to the fourth source or drain region, wherein the second channel region has a width perpendicular to its length and parallel to the surface of the substrate, wherein the width of the channel region is less than 80% of the width of the second channel region.

Example 4 includes the subject matter of any of Examples 1-3, and wherein a width of the third source or drain region is within 10% of the width of the first source or drain region, wherein a width of the second channel region is within 10% of the width of the first source or drain region, wherein a width of the fourth source or drain region is within 10% of the width of the first source or drain region.

Example 5 includes the subject matter of any of Examples 1-4, and wherein the channel region has a thickness perpendicular to its width and length, wherein the second channel region has a thickness perpendicular to its width and length, wherein the thickness of the channel region is less than 80% of the thickness of the second channel region.

Example 6 includes the subject matter of any of Examples 1-5, and wherein the channel region has a thickness perpendicular to its width and length, wherein the second channel region has a thickness perpendicular to its width and length, wherein the thickness of the channel region is within 10% of the thickness of the second channel region.

Example 7 includes the subject matter of any of Examples 1-6, and wherein an area of the first source or drain region near an interface with the channel region is partially etched more than a corresponding area of the third source or drain region near an interface with the second channel region.

Example 8 includes the subject matter of any of Examples 1-7, and wherein the semiconductor nanoribbon is between the substrate and the second semiconductor nanoribbon.

Example 9 includes the subject matter of any of Examples 1-8, and wherein the second semiconductor nanoribbon is between the substrate and the semiconductor nanoribbon.

Example 10 includes the subject matter of any of Examples 1-9, and wherein the one or more transistors comprise a PMOS transistor and an NMOS transistor, wherein the semiconductor nanoribbon corresponds to one of the PMOS transistor and the NMOS transistor and the second semiconductor nanoribbon corresponds to the other of the PMOS transistor and the NMOS transistor, wherein a gate of the NMOS transistor is connected to a gate of the PMOS transistor.

Example 11 includes the subject matter of any of Examples 1-10, and wherein a separation between the NMOS transistor and the PMOS transistor is less than 30 nanometers.

Example 12 includes the subject matter of any of Examples 1-11, and further including a second plurality of semiconductor nanoribbons located on the substrate, wherein the second plurality of semiconductor nanoribbons is next to the plurality of semiconductor nanoribbons, wherein, at a distance from the substrate where the plurality of semiconductor nanoribbons has the semiconductor nanoribbon, the second plurality of semiconductor nanoribbons comprises a third semiconductor nanoribbon comprising a fifth source or drain region; a third channel region; and a sixth source or drain region, wherein the third channel region is connected to the fifth source or drain region and the sixth source or drain region, wherein, at a distance from the substrate where the plurality of semiconductor nanoribbons has the second semiconductor nanoribbon, the second plurality of semiconductor nanoribbons comprises a fourth semiconductor nanoribbon comprising a seventh source or drain region; a fourth channel region; and an eighth source or drain region, wherein the fourth channel region is connected to the seventh source or drain region and the eighth source or drain region, wherein a width of the third channel region is within 10% of a width of the fourth channel region.

Example 13 includes a processor comprising the device of any of Examples 1-12.

Example 14 includes a system comprising the processor of Example 13 and one or more memory devices.

Example 15 includes a device comprising a substrate; a first transistor located on the substrate, wherein the first transistor comprises a first plurality of nanoribbons stacked on top of each other, wherein a width of a channel region of individual nanoribbons of the first plurality of nanoribbons is less than 80% of a width of a source or drain region for the corresponding nanoribbon of the first plurality of nanoribbons; and a second transistor located on the substrate next to the first transistor, wherein the second transistor comprises a plurality of nanoribbons stacked on top of each other, wherein a width of a channel region of individual nanoribbons of the second plurality of nanoribbons is within 10% of a width of a source or drain region for the corresponding nanoribbon of the second plurality of nanoribbons.

Example 16 includes the subject matter of Example 15, and wherein, for individual nanoribbons of the first plurality of nanoribbons, a height of a channel region of individual nanoribbons of the first plurality of nanoribbons is less than 80% of a height of a source or drain region for the corresponding nanoribbon of the first plurality of nanoribbons.

Example 17 includes the subject matter of any of Examples 15 and 16, and further including a third transistor located on the first transistor.

Example 18 includes the subject matter of any of Examples 15-17, and further including a third transistor, wherein the first transistor is located on the second transistor.

Example 19 includes a processor comprising the device of any of Examples 15-18.

Example 20 includes a system comprising the processor of Example 19 and one or more memory devices.

Example 21 includes a method comprising forming a plurality of semiconductor nanoribbons on a substrate, wherein the plurality of semiconductor nanoribbons are stacked on top of each other above the substrate, wherein individual semiconductor nanoribbons of the plurality of semiconductor nanoribbons comprise a first source or drain region, a channel region, and a second source or drain region; depositing a mask around the channel regions of the plurality of semiconductor nanoribbons; recessing the mask to expose a first set of one or more semiconductor nanoribbons of the plurality of semiconductor nanoribbons without exposing a second set of one or more semiconductor nanoribbons of the plurality of semiconductor nanoribbons; and partially etching the channel regions of the first set of one or more semiconductor nanoribbons to narrow the channel regions of the first set of one or more semiconductor nanoribbons without etching the channel regions of the second set of one or more semiconductor nanoribbons.

Example 22 includes the subject matter of Example 21, and wherein forming the plurality of semiconductor nanoribbons comprises forming a stack comprising alternating layers of channel regions and inter-nanoribbon layers, wherein depositing the mask around the channel regions of the plurality of semiconductor nanoribbons comprises depositing the mask around the channel regions of the plurality of semiconductor nanoribbons and the inter-nanoribbon layers, wherein partially etching the channel regions of the first set of one or more semiconductor nanoribbons to narrow the channel regions of the first set of one or more semiconductor nanoribbons comprises partially etching the channel regions of the first set of one or more semiconductor nanoribbons and the inter-nanoribbon layers between the channel regions of the first set of one or more semiconductor nanoribbons to narrow the channel regions of the first set of one or more semiconductor nanoribbons and the inter-nanoribbon layers between the channel regions of the first set of one or more semiconductor nanoribbons.

Example 23 includes the subject matter of any of Examples 21 and 22, and further including etching the inter-nanoribbon layers to release the channel regions of the plurality of semiconductor nanoribbons, wherein etching the inter-nanoribbon layers comprises partially etching the first source or drain region and the second source or drain region of the first set of one or more semiconductor nanoribbons where narrowing of the channel regions of the first set of one or more semiconductor nanoribbons exposed the first source or drain region and the second source or drain region of the first set of one or more semiconductor nanoribbons.

Example 24 includes the subject matter of any of Examples 21-23, and wherein the inter-nanoribbon layers comprise silicon and germanium, wherein the first source or drain region and the second source or drain region of the first set of one or more semiconductor nanoribbons comprise silicon and germanium.

Example 25 includes the subject matter of any of Examples 21-24, and wherein partially etching the channel regions of the first set of one or more semiconductor nanoribbons to narrow the channel regions of the first set of one or more semiconductor nanoribbons comprises partially etching the channel regions of the first set of one or more semiconductor nanoribbons to narrow and thin the channel regions of the first set of one or more semiconductor nanoribbons.

Example 26 includes the subject matter of any of Examples 21-25, and wherein the mask is a hard mask comprising carbon.

Example 27 includes a method comprising forming a plurality of semiconductor nanoribbons on a substrate, wherein the plurality of semiconductor nanoribbons are stacked on top of each other above the substrate, wherein individual semiconductor nanoribbons of the plurality of semiconductor nanoribbons comprise a first source or drain region, a channel region, and a second source or drain region; depositing a liner over the channel region of a first set of one or more semiconductor nanoribbons of the plurality of semiconductor nanoribbons; and partially etching the channel regions of a second set of one or more semiconductor nanoribbons of the plurality of semiconductor nanoribbons to narrow the channel regions of the second set of one or more semiconductor nanoribbons without etching the channel regions of the first set of one or more semiconductor nanoribbons.

Example 28 includes the subject matter of Example 27, and wherein depositing the liner comprises depositing a mask around the channel regions of the plurality of semiconductor nanoribbons; recessing the mask to expose the first set of one or more semiconductor nanoribbons; and depositing the liner around the channel regions of the first set of one or more semiconductor nanoribbons while the mask covers the second set of one or more semiconductor nanoribbons.

Example 29 includes the subject matter of any of Examples 27 and 28, and wherein forming the plurality of semiconductor nanoribbons comprises forming a stack comprising alternating layers of channel regions and inter-nanoribbon layers, wherein depositing the liner over the channel regions of the plurality of semiconductor nanoribbons comprises depositing the liner over the channel regions of the first set of one or more semiconductor nanoribbons and the inter-nanoribbon layers between the first set of one or more semiconductor nanoribbons, wherein partially etching the channel regions of the second set of one or more semiconductor nanoribbons to narrow the channel regions of the second set of one or more semiconductor nanoribbons comprises partially etching the channel regions of the second set of one or more semiconductor nanoribbons and the inter-nanoribbon layers between the channel regions of the second set of one or more semiconductor nanoribbons to narrow the channel regions of the second set of one or more semiconductor nanoribbons and the inter-nanoribbon layers between the channel regions of the second set of one or more semiconductor nanoribbons.

Example 30 includes the subject matter of any of Examples 27-29, and further including etching the inter-nanoribbon layers to release the channel regions of the plurality of semiconductor nanoribbons, wherein etching the inter-nanoribbon layers comprises partially etching the first source or drain region and the second source or drain region of the second set of one or more semiconductor nanoribbons where narrowing of the channel regions of the second set of one or more semiconductor nanoribbons exposed the first source or drain region and the second source or drain region of the second set of one or more semiconductor nanoribbons.

Example 31 includes the subject matter of any of Examples 27-30, and wherein the inter-nanoribbon layers comprise silicon and germanium, wherein the first source or drain region and the second source or drain region of the second set of one or more semiconductor nanoribbons comprise silicon and germanium.

Example 32 includes the subject matter of any of Examples 27-31, and wherein partially etching the channel regions of the second set of one or more semiconductor nanoribbons to narrow the channel regions of the second set of one or more semiconductor nanoribbons comprises partially etching the channel regions of the second set of one or more semiconductor nanoribbons to narrow and thin the channel regions of the second set of one or more semiconductor nanoribbons.

Example 33 includes the subject matter of any of Examples 27-32, and wherein the liner comprises titanium and nitrogen.

Example 34 includes the subject matter of any of Examples 27-33, and wherein the liner comprises aluminum and oxygen.

Example 35 includes the subject matter of any of Examples 27-34, and wherein the liner comprises silicon and oxygen.

Example 36 includes the subject matter of any of Examples 27-35, and wherein the liner comprises silicon and nitrogen.

1. A device comprising:
a substrate;
one or more transistors on a surface of the substrate, the one or more transistors comprising:
a semiconductor nanoribbon comprising:
a first source or drain region;
a channel region; and
a second source or drain region,
wherein the channel region has a length extending from the first source or drain region to the second source or drain region, wherein the channel region has a width perpendicular to the length and parallel to the surface of the substrate,
wherein the width of the channel region is at least 20% less than a width of the first source or drain region and a width of the second source or drain region.

2. The device of claim 1, wherein the channel region has a thickness perpendicular to its width and length,
wherein the channel region has a thickness that is less than 80% of a thickness of the first source or drain region.

3. The device of claim 1, wherein the one or more transistors comprise a plurality of semiconductor nanoribbons, wherein the plurality of semiconductor nanoribbons are stacked on top of each other above the substrate, the plurality of semiconductor nanoribbons comprising:
the semiconductor nanoribbon; and
a second semiconductor nanoribbon comprising
a third source or drain region;
a second channel region; and
a fourth source or drain region,
wherein the second channel region has a length extending from the second source or drain region to the fourth source or drain region, wherein the second channel region has a width perpendicular to its length and parallel to the surface of the substrate,
wherein the width of the channel region is less than 80% of the width of the second channel region.

4. The device of claim 3,
wherein a width of the third source or drain region is within 10% of the width of the first source or drain region,
wherein a width of the second channel region is within 10% of the width of the first source or drain region,
wherein a width of the fourth source or drain region is within 10% of the width of the first source or drain region.

5. The device of claim 3, wherein the channel region has a thickness perpendicular to its width and length,
wherein the second channel region has a thickness perpendicular to its width and length,
wherein the thickness of the channel region is less than 80% of the thickness of the second channel region.

6. The device of claim 3, wherein the channel region has a thickness perpendicular to its width and length,
wherein the second channel region has a thickness perpendicular to its width and length,
wherein the thickness of the channel region is within 10% of the thickness of the second channel region.

7. The device of claim 3, wherein an area of the first source or drain region near an interface with the channel region is partially etched more than a corresponding area of the third source or drain region near an interface with the second channel region.

8. The device of claim 3, wherein the semiconductor nanoribbon is between the substrate and the second semiconductor nanoribbon.

9. The device of claim 3, wherein the second semiconductor nanoribbon is between the substrate and the semiconductor nanoribbon.

10. The device of claim 3, wherein the one or more transistors comprise a PMOS transistor and an NMOS transistor, wherein the semiconductor nanoribbon corresponds to one of the PMOS transistor and the NMOS transistor and the second semiconductor nanoribbon corresponds to the other of the PMOS transistor and the NMOS transistor, wherein a gate of the NMOS transistor is connected to a gate of the PMOS transistor.

11. The device of claim 10, wherein a separation between the NMOS transistor and the PMOS transistor is less than 30 nanometers.

12. The device of claim 3, further comprising:
a second plurality of semiconductor nanoribbons located on the substrate, wherein the second plurality of semiconductor nanoribbons is next to the plurality of semiconductor nanoribbons,
wherein, at a distance from the substrate where the plurality of semiconductor nanoribbons has the semiconductor nanoribbon, the second plurality of semiconductor nanoribbons comprises a third semiconductor nanoribbon comprising:
a fifth source or drain region;
a third channel region; and
a sixth source or drain region, wherein the third channel region is connected to the fifth source or drain region and the sixth source or drain region,
wherein, at a distance from the substrate where the plurality of semiconductor nanoribbons has the second semiconductor nanoribbon, the second plurality of semiconductor nanoribbons comprises a fourth semiconductor nanoribbon comprising:
a seventh source or drain region;
a fourth channel region; and
an eighth source or drain region, wherein the fourth channel region is connected to the seventh source or drain region and the eighth source or drain region,
wherein a width of the third channel region is within 10% of a width of the fourth channel region.

13. A processor comprising the device of claim 1.

14. A device comprising:
a substrate;
a first transistor located on the substrate, wherein the first transistor comprises a first plurality of nanoribbons stacked on top of each other, wherein a width of a channel region of individual nanoribbons of the first plurality of nanoribbons is less than 80% of a width of a source or drain region for the corresponding nanoribbon of the first plurality of nanoribbons; and
a second transistor located on the substrate next to the first transistor, wherein the second transistor comprises a plurality of nanoribbons stacked on top of each other, wherein a width of a channel region of individual nanoribbons of the second plurality of nanoribbons is within 10% of a width of a source or drain region for the corresponding nanoribbon of the second plurality of nanoribbons.

15. The device of claim 14, wherein, for individual nanoribbons of the first plurality of nanoribbons, a height of a channel region of individual nanoribbons of the first plurality of nanoribbons is less than 80% of a height of a source or drain region for the corresponding nanoribbon of the first plurality of nanoribbons.

16. The device of claim 14, further comprising a third transistor located on the first transistor.

17. The device of claim 14, further comprising a third transistor, wherein the first transistor is located on the second transistor.

18. A method comprising:
forming a plurality of semiconductor nanoribbons on a substrate, wherein the plurality of semiconductor nanoribbons are stacked on top of each other above the substrate, wherein individual semiconductor nanoribbons of the plurality of semiconductor nanoribbons comprise a first source or drain region, a channel region, and a second source or drain region;
depositing a mask around the channel regions of the plurality of semiconductor nanoribbons;
recessing the mask to expose a first set of one or more semiconductor nanoribbons of the plurality of semiconductor nanoribbons without exposing a second set of one or more semiconductor nanoribbons of the plurality of semiconductor nanoribbons; and
partially etching the channel regions of the first set of one or more semiconductor nanoribbons to narrow the channel regions of the first set of one or more semiconductor nanoribbons without etching the channel regions of the second set of one or more semiconductor nanoribbons.

19. The method of claim 18, wherein forming the plurality of semiconductor nanoribbons comprises forming a stack comprising alternating layers of channel regions and inter-nanoribbon layers,
wherein depositing the mask around the channel regions of the plurality of semiconductor nanoribbons comprises depositing the mask around the channel regions of the plurality of semiconductor nanoribbons and the inter-nanoribbon layers,
wherein partially etching the channel regions of the first set of one or more semiconductor nanoribbons to narrow the channel regions of the first set of one or more semiconductor nanoribbons comprises partially etching the channel regions of the first set of one or more semiconductor nanoribbons and the inter-nanoribbon layers between the channel regions of the first set of one or more semiconductor nanoribbons to narrow the channel regions of the first set of one or more semiconductor nanoribbons and the inter-nanoribbon layers between the channel regions of the first set of one or more semiconductor nanoribbons.

20. The method of claim 19, further comprising etching the inter-nanoribbon layers to release the channel regions of the plurality of semiconductor nanoribbons,
wherein etching the inter-nanoribbon layers comprises partially etching the first source or drain region and the second source or drain region of the first set of one or more semiconductor nanoribbons where narrowing of the channel regions of the first set of one or more semiconductor nanoribbons exposed the first source or drain region and the second source or drain region of the first set of one or more semiconductor nanoribbons.
